(19) United States
(12) Patent Application Publication
(10) Pub. No.: US 2026/0255861 A1
(43) Pub. Date: Aug. 27, 2026

(54) DISPLAY DEVICE

(71) Applicant: LG Display Co., Ltd., Seoul (KR)

(72) Inventors: Byung-Gwan HYUN, Paju-si (KR); Hye-Jeong PARK, Paju-si (KR); Won-Rae KIM, Paju-si (KR); Kyung-Kook JANG, Paju-si (KR)

(21) Appl. No.: 19/372,460

(22) Filed: Oct. 29, 2025

(30) Foreign Application Priority Data
Feb. 27, 2025 (KR) 10-2025-0025550

(51) Int. Cl. H10K 59/80; H10K 59/122

(52) U.S. Cl. CPC H10K 59/8792; H10K 59/122

(57) ABSTRACT

A display device including a substrate having a non-display area and a display area, the display area including an emission area and a non-emission area; a light-emitting diode disposed in the emission area; a bank layer disposed adjacently to the light-emitting diode in the non-emission area; an encapsulation layer disposed on the light-emitting diode and the bank layer; a color filter pattern disposed on the encapsulation layer in the emission area; a black matrix disposed on the encapsulation layer in the non-emission area; and an auxiliary black matrix disposed on the substrate in the non-display area, and on the color filter pattern and the black matrix in the display area, in which the auxiliary black matrix disposed in the non-display area has a first thickness that is thicker than a second thickness of the auxiliary black matrix disposed in the display area.

### CROSS REFERENCE TO RELATED APPLICATION

This application claims priority from and the benefit of Korean Patent Application No. 10-2025-0025550, filed on Feb. 27, 2025, which is hereby incorporated by reference for all purposes as if fully set forth herein.

### BACKGROUND

### Field

Embodiments of the invention relate generally to a display device, and more particularly, to a display device capable of implementing a uniform reflection visibility in an entire area and minimizing a reflection of an external light.

### Discussion of the Background

Various display devices for displaying images in TV, a monitor, a smart phone, a tablet PC and a notebook computer have been utilized. The display devices include a display panel having multiple light emitting elements or liquid crystals for implementing images and transistors for controlling each light emitting element or liquid crystal so that the display devices display desired images through the multiple light emitting element or the liquid crystals.

Technologies for a light emitting display device including a light-emitting diode as one of the display devices have been developed rapidly. The light emitting display device may be divided into an organic light emitting display device using organic luminescent materials and an inorganic light emitting display device using inorganic luminescent materials.

The display device typically includes a polarizing plate on a display surface so as to minimize or reduce external light reflection. Recently, various research and developments have been performed for improving reliability and image quality of the display devices.

The above information disclosed in this Background section is only for understanding of the background of the inventive concepts, and, therefore, it may contain information that does not constitute prior art.

### SUMMARY

Accordingly, one or more embodiments of the inventive concepts are directed to a display device that substantially obviates one or more of the problems due to the limitations and disadvantages of the related art.

Additional features of the inventive concepts will be set forth in the description which follows, and in part will be apparent from the description, or may be learned by practice of the inventive concepts.

An aspect of the inventive concepts is to provide a display device capable of minimizing or reducing a reflection of an external light while maintaining or improving luminance, and with preventing lowering or reducing the luminance.

Another aspect of the inventive concepts is to provide a display device capable of minimizing or reducing stains and a rainbow mura caused by the external light, light reflection from conductive materials such as a conductive film and/or electrode in a display panel and/or refractive index differences among the films through which the light is passed through.

Another aspect of the inventive concepts is to provide a display device capable of controlling an external light path on a display surface so that the external light may be uniformly incident in the whole area and minimizing or reducing a deviation in the reflection of the external light by an area.

Another aspect of the inventive concepts is to provide a display device with improved black visibility in a display area and a non-display area by overcoming the difference in length of different external light paths in the display area and the non-display area.

Another aspect of the inventive concepts is to provide a display device capable of improving flexibility and applying to a foldable product.

Another aspect of the inventive concepts is to provide a display device capable of removing a polarizing member.

Another aspect of the inventive concepts is to provide a display device capable of minimizing or reducing reflection visibility by an area.

Another aspect of the inventive concepts is to provide a display device that implements low reflection and low power, thereby being environmentally friendly and pursuing ESG (Environmental, Social and Governance).

A display device according to an embodiment includes a substrate having a non-display area and a display area including an emission area and a non-emission area; a light-emitting diode disposed on the substrate corresponding to the emission area; a bank layer disposed adjacently to the light-emitting diode corresponding to the non-emission area; an encapsulation layer disposed on the light-emitting diode and the bank layer; a color filter pattern disposed on the encapsulation layer corresponding to the emission area; a black matrix disposed on the encapsulation layer corresponding to the non-emission area; and an auxiliary black matrix disposed on the substrate in the non-display area and on the color filter pattern and the black matrix in the display area, in which the auxiliary black matrix disposed in the non-display area has a first thickness that is thicker than a second thickness of the auxiliary black matrix disposed in the display area.

A thickness of the auxiliary black matrix positioned correspondingly to the emission area on the color filter pattern may be a substantially same as or different from a thickness of the auxiliary black matrix positioned correspondingly to the non-emission area on the black matrix.

The non-emission area may include a first non-emission area where the bank layer and the black matrix are disposed to overlap; and a second non-emission area where the bank layer is disposed to extend further toward the emission area than the black matrix.

A thickness of the auxiliary black matrix positioned correspondingly to the first non-emission area and/or a thickness of the auxiliary black matrix positioned correspondingly to the emission area on the color filter pattern may be different from a thickness of the auxiliary black matrix positioned correspondingly to the second non-emission area.

The second thickness may gradually decrease from the auxiliary black matrix disposed in the non-emission area to the auxiliary black matrix disposed in the emission area.

The black matrix may include a first black matrix disposed on the encapsulation layer corresponding to the non-emission area; and a second black matrix disposed on the first black matrix corresponding to the non-emission area.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of embodiments of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 illustrates a schematic functional diagram of a display device in accordance with one or more embodiments of the inventive concepts.

FIG. 2 illustrates a schematic circuit diagram of a display device in one or more embodiments of the inventive concepts.

FIG. 3 illustrates a cross-sectional view taken along line III-III′ shown in FIG. 1 and illustrates a schematic cross-sectional view of a display device in accordance with a first embodiment of the inventive concepts.

FIG. 4 is a schematic diagram illustrating components of a bank layer, a black matrix and an auxiliary black matrix with related to an optical density by areas in the display device in accordance with the first embodiment of the inventive concepts.

FIGS. 5, 6, 7, 8, and 9 are schematic diagrams illustrating components of the bank layer, the black matrix and the auxiliary black matrix in the display device in accordance with various other embodiments of the inventive concepts.

FIG. 10 illustrates a cross-sectional view taken along line II-II′ shown in FIG. 1 and illustrates a schematic cross-sectional view of a display device in accordance with a second embodiment of the inventive concepts.

FIG. 11 is a schematic diagram illustrating components of a bank layer, a black matrix and an auxiliary black matrix with related to an optical density by areas in the display device in accordance with the second embodiment of the inventive concepts.

FIGS. 12, 13, 14, 15, and 16 are schematic diagrams illustrating components of the bank layer, the black matrix and the auxiliary black matrix in the display device in accordance with various other embodiments of the inventive concepts.

FIG. 17 illustrates a schematic exploded perspective view of a display device in accordance with a third embodiment of the inventive concepts.

FIG. 18 illustrates a schematic cross-sectional view of the display device in accordance with the third embodiment of the inventive concepts.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/of” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” may encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

In analyzing a component, an error range should be interpreted as being included even where there is no explicit description.

In describing a temporal relationship, for example, where a temporal predecessor relationship is described as being “after,” “subsequent,” “next to,” “prior to,” or the like, unless a more limiting term like “immediately” or “directly” is used, cases that are not continuous or sequential may also be included. Further, the term “can” fully encompasses all the meanings and coverages of the term “may” and vice versa.

Features of various embodiments of the inventive concepts may be partially or entirely united or combined with each other, technically various interlocking and driving are possible, and each of the embodiments may be independently implemented with respect to each other or implemented together in a co-dependent relationship.

All the components of each display device according to all embodiments of the inventive concepts are operatively coupled and configured.

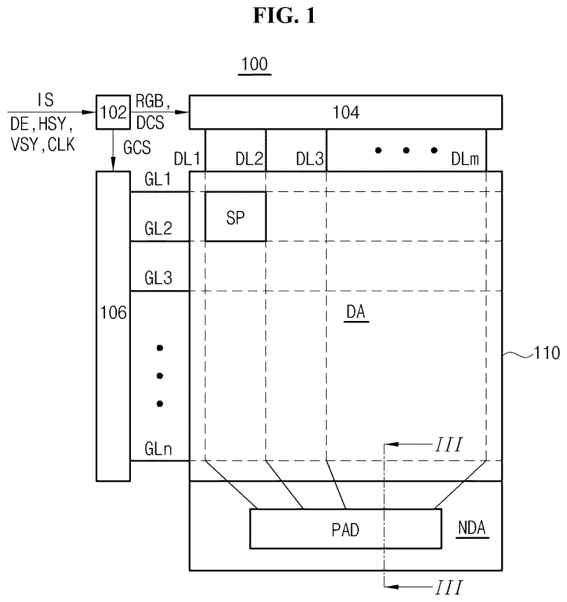

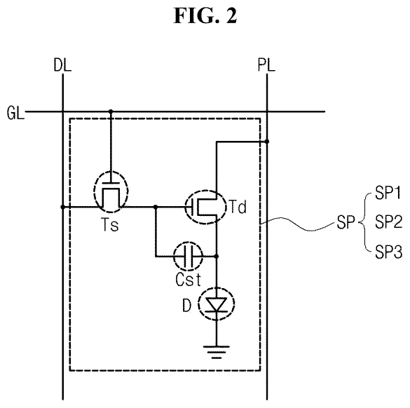

FIG. 1 illustrates a schematic functional diagram of a display device in accordance with one or more embodiments of the inventive concepts. FIG. 2 illustrates a schematic circuit diagram of a display device in one or more embodiments of the inventive concepts.

Referring to FIGS. 1 and 2, the display device 100 in accordance with one or more embodiments of the inventive concepts includes a timing controller 102, a data driver 104, a gate driver 106, and a substrate 110 on which a display panel is poisoned. A plurality of data lines DL1, DL2, DL3, . . . DLm (m is an integer) and a plurality of gate lines GL1, GL2, GL3, . . . GLn (n is an integer) may be arranged on the substrate 110.

The timing controller 102 is configured to generate a gate control signal GCS, a data control signal DCS, and an image data RGB using a plurality of timing signals such as an image signal IS, a data enable signal DE, a horizontal synchronization signal HSV, a clock CLK and the likes supplied from an external system such as a graphic card and/or TV system. The timing controller 102 may provide the generated data control signal DCS and the image data RGB to the data driver 104 and the generated gate control signal GCS to the gate driver 106.

The data driver 104 may generate a data signal (data voltage) using the data control signal DCS and the image data RGB supplied from the timing controller 102, and provide the generated data signal to the data line DLs positioned on the substrate 108.

The gate driver 106 may generate a gate signal (gate voltage) using the gate control signal GCS supplied from the timing controller 102, and provide the generated gate signal to the gate lines GLs positioned on the substrate 110. The gate driver 106 may be positioned on one side of the substrate 110 or two separated gate drivers may be positioned on both sides of the substrate 110, respectively, by the driving types.

The substrate 110 may include a display area DA displaying an image and including a plurality of sub-pixel regions SPs, and a non-display area NDA surrounding the display area DA. The display panel may be disposed on the display area DA of the substrate 110.

The non-display area NDA may be positioned outside of the display area DA, such as proximate or on an edge of the substrate 110. A pad member PAD may be disposed in the non-display area NDA. The pad member PAD may be connected to an electrode disposed in the display panel through output lines and may be connected to the data driver 104 and/or the gate driver 106 through input lines.

An image may be displayed in the display area DA of the substrate 110 using the gate signal and the data signal. In particular, the substrate 110 may include the plurality of sub-pixel regions SPs, the plurality of gate lines GLs, the plurality of data lines DLs, and a plurality of power lines PLs for displaying the image.

With reference to FIG. 2, a gate line GL, a data line DL, and a power line PL may cross each other to define a sub-pixel region SP in the display device 100. A switching thin film transistor Ts, a driving thin film transistor Td, a storage capacitor Cst and a light-emitting diode D may be disposed in the sub-pixel region SP. The sub-pixel region SP may include a first sub-pixel region SP1, a second sub-pixel region SP2, a third sub-pixel region SP3, and optionally, a fourth sub-pixel region. As an example, the first sub-pixel region SP may be a red (R) sub-pixel region, the second sub-pixel region SP2 may be a green (G) sub-pixel region, the third sub-pixel region SP3 may be a blue (B) sub-pixel region, and the fourth sub-pixel region may be a white (W) sub-pixel region, but these regions are not limited in this regard.

The switching thin film transistor Ts may be connected to the gate line GL and the data line DL. The driving thin film transistor Td and the storage capacitor Cst may be connected between the switching thin film transistor Ts and the power line PL, and the light-emitting diode D may be connected to the driving thin film transistor Td.

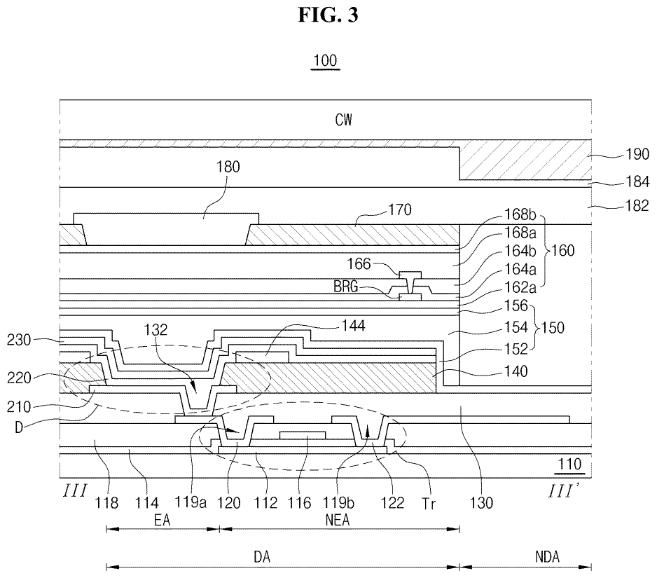

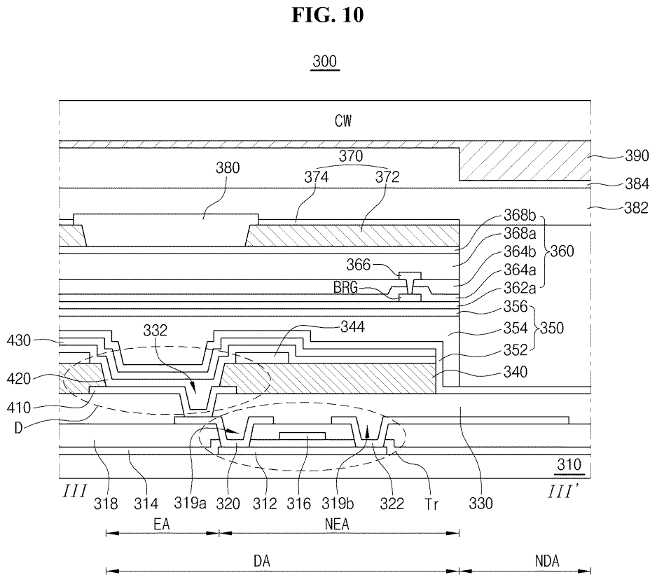

In the display device, when the switching thin film transistor Ts is turned on by a gate signal applied to the gate line GL, a data signal applied to the data line DL may be applied to a gate electrode 116 or 316 (FIG. 3 or FIG. 10) and to one electrode of the storage capacitor Cst through the switching thin film transistor Ts.

The driving thin film transistor Td may be turned on by the data signal applied to the gate electrode 116 or 316 so that a current proportional to the data signal may be supplied from the power line PL to the light-emitting diode D through the driving thin film transistor Td. And then, the light-emitting diode D emits light with a luminance proportional to the current flowing through the driving thin film transistor Td. In this case, the storage capacitor Cst is charged with a voltage proportional to the data signal so that the voltage of the gate electrode 116 or 316 in the driving thin film transistor Td is kept constant during one frame. Therefore, the display device may display a desired image.

In one embodiment, each of the switching thin film transistor Ts and/or the driving thin film transistor Td may include, but is not limited to, a polycrystalline semiconductor material such as low temperature polycrystalline silicon (LTPS) and/or an oxide semiconductor. For example, the switching thin film transistor Ts and/or the driving thin film transistor Td may be a transistor of a low temperature polycrystalline and oxide (LPTO) type including the LPTS and the oxide semiconductor, but is not limited thereto. In another embodiment, the driving thin film transistor Td may be a transistor of a Complementary Metal Oxide Semiconductor (CMOS) type combining a p-Channel Metal Oxide Semiconductor (PMOS) and an n-Channel Metal Oxide Semiconductor (NMOS), but is not limited thereto.

### First Embodiment

FIG. 3 illustrates a cross-sectional view taken along line III-III′ of FIG. 1 and illustrates a schematic cross-sectional view of a display device in accordance with a first embodiment of the inventive concepts.

Referring to FIG. 3, a display device 100 includes a substrate 110, a thin film transistor Tr and a light-emitting diode D disposed in each sub-pixel region SP. The display device 100 may include a bank layer 140 disposed adjacently to the light-emitting diode D, a black matrix 170 disposed on the bank layer 140, a color filter pattern 180 disposed on the light-emitting diode D, and an auxiliary black matrix 190 disposed on the black matrix 170 and the color filter pattern 180.

The substrate 110 may include the display area DA for displaying an image and the non-display area NDA surrounding the display area DA. The display area DA may include an emission area EA where the light emitted from the light-emitting diode D is transmitted, and a non-emission area NEA surrounding the emission area EA.

The substrate 110 may include, but is not limited to, a glass substrate, a flexible substrate or a polymer plastics substrate. For example, the substrate 110 may be configured to have at least one of a polyimide (PI) substrate, a polyether sulfone (PES) substrate, a polyethylene naphthalate (PEN) substrate, a polyethylene terephthalate (PET) substrate and a polycarbonate (PC) substrate.

The thin film transistor Tr may be disposed on the substrate 110. In FIG. 3, the thin film transistor Tr is exemplarily illustrated as being directly disposed on the substrate 110, however the inventive concepts are not limited thereto. In some embodiments, a buffer layer may be disposed on the substrate 110, and the thin film transistor Tr may be disposed on the buffer layer. For example, the buffer layer may include, but is not limited to, silicon oxide (SiOₓ) and/or silicon nitride (SiNₓ,) (wherein 0<x≤2).

The thin film transistor Tr may include a semiconductor layer 112, a gate electrode 116, a source electrode 120 and a drain electrode 122. The thin film transistor Tr may be the driving thin film transistor Td (FIG. 2).

The semiconductor layer 112 may be disposed on the substrate 110. In one embodiment, the semiconductor layer 112 may include an oxide semiconductor material. For example, the oxide semiconductor may be selected from, but is not limited to, Indium Gallium Zinc oxide (IGZO), Indium Zinc Tin oxide (IZTO), Zinc Gallium Tin oxide (ZGTO), Zinc Tin oxide (ZTO), Zinc Gallium oxide (ZGO), Zinc oxide (ZnO) and combinations thereof.

When the semiconductor layer 112 includes the oxide semiconductor material, a light shielding pattern may be disposed under the semiconductor layer 112. The light shielding pattern may prevent or reduce the light from being incident to the semiconductor layer 112, and thereby the semiconductor layer 112 from being deteriorated by the light. In another embodiment, the semiconductor layer 112 may include a polycrystalline semiconductor. In this case, impurity may be doped to both sides of the semiconductor layer 112.

A gate insulating layer 114 may be disposed on the semiconductor layer 112 for covering the entire substrate 110. For example, the gate insulating layer 114 may include, but is not limited to, an inorganic insulating material such as silicon oxide (SiOₓ) and/or silicon nitride (SiNₓ) (wherein 0<x≤2).

The gate electrode 116 may include a conductive material such as metal, and be disposed on the gate insulating layer 114, which may correspond to a center of the semiconductor layer 112. For example, the gate electrode 116 may include, but is not limited to, a metal component such as copper (Cu), molybdenum (Mo), titanium (Ti), aluminum (Al), gold (Au), and silver (Ag). The gate electrode 116 may have a mono-layer structure or a multi-layer structure. In FIG. 3, while the gate insulating layer 114 is exemplarily illustrated as being disposed on the entire substrate 110, in other embodiments, the gate insulating layer 114 may be patterned to have a shape forming to that of the gate electrode 116.

An interlayer insulating layer 118 may be disposed on the gate electrode 116 for covering the entire substrate 110. For example, the interlayer insulating layer 118 may include, but is not limited to, an inorganic insulating material such as silicon oxide (SiOₓ) and silicon nitride (SiNₓ) (wherein 0<x≤2) or an organic insulating material such as benzocyclobutene and/or photo-acryl.

The interlayer insulating layer 118 may have first and second semiconductor contact holes 119a and 119b that expose or do not cover both sides of the semiconductor layer 112. The first and second semiconductor contact holes 119a and 119b may be spaced apart from the gate electrode 116 at both sides of the gate electrode 116. In FIG. 3, the first and second semiconductor contact holes 119a and 119b are configured to be disposed in the interlayer insulating layer 118 and the gate insulating layer 114. In another embodiment, when the gate insulating layer 114 is patterned as the gate electrode 116, the first and second semiconductor contact holes 119a and 119b may be formed in only the interlayer insulating layer 118.

The source electrode 120 and the drain electrode 122, which may include a conductive material such as metal component may be disposed on the interlayer insulating layer 118. The source electrode 120 and the drain electrode 122 may be spaced apart from each other with centering the gate electrode 116, and electrically contact to both sides of the semiconductor layer 112 through the first and second semiconductor contact holes 119a and 119b. In one embodiment, the source electrode 120 may be an input electrode connecting to a high potential driving power, and the drain electrode 122 may be an output electrode connecting to a switch circuit, although the source and drain electrodes 120 and 122 are not so limited. The amount of current flowing to the light-emitting diode D may be controlled by voltage differences between the gate electrode 116 and the source electrode 120.

For example, the source electrode 120 and the drain electrode 122 may include, but are not limited to, the metal component such as copper (Cu), molybdenum (Mo), titanium (Ti), aluminum (Al), gold (Au) and/or silver (Ag). The source electrode 120 and the drain electrode 122 may have a mono-layer structure or a multi-layer structure.

In FIG. 3, the thin film transistor Tr may have a coplanar structure where the gate electrode 116, the source electrode 120 and the drain electrode 122 are disposed on the semiconductor layer 112. In another embodiment, the thin film transistor may have an inverted staggered structure where the gate electrode is disposed under the semiconductor layer and the source electrode and the drain electrode are disposed on the semiconductor layer. In this case, the semiconductor layer may include amorphous silicon.

The thin film transistor Tr may be the driving thin film transistor Td (FIG. 2). For example, the driving thin film transistor Td may include the oxide semiconductor, although the inventive concepts are not so limited.

The pad member PAD (FIG. 1) may be disposed in the non-display area NDA. In one embodiment, the pad member PAD may be connected to the drain electrode 122 and may constitute the same layer and the same material as the source electrode 120 and the drain electrode 122. In another embodiment, the pad member PAD may be connected to a gate electrode of the switching thin film transistor Ts (FIG. 2) and may constitute the same layer and the same material as the gate electrode of the switching thin film transistor Ts.

A planarization layer 130 is disposed on the source electrode 120 and the drain electrode 122 for covering the entire substrate 110. The planarization layer 130 may be disposed for covering the thin film transistor Tr.

The planarization layer 130 may have a flat surface and a contact hole 132 that exposes or does not cover the source electrode 120 or the drain electrode 122. For example, the planarization layer 130 may include, but is not limited to, an inorganic insulating material such as silicon oxide (SiOₓ) and silicon nitride (SiNₓ) (wherein 0<x≤2) or an organic insulating material such as benzocyclobutene and/or photo-acryl.

The light-emitting diode D may be disposed on the planarization layer 130 correspondingly to the emission area EA. The light-emitting diode D may include a first electrode 210 disposed on the planarization layer 130 and connected to the source electrode 120 or the drain electrode 122, and an emissive layer 220 and a second electrode 230 that are laminated sequentially on the first electrode 210. As an example, the light-emitting diode D may be positioned in each of the red sub-pixel region, the green sub-pixel region, the blue sub-pixel region, and optionally the white sub-pixel region and may emit red light, green light, blue light and white light, respectively.

The first electrode 210 may be disposed separately in each sub-pixel region SP. The first electrode 210 may be an anode and may include a conductive material with relatively high work function value, for example, a transparent conductive oxide (TCO). For example, the first electrode 210 may include, but is not limited to, Indium Tin oxide (ITO), Indium Zinc oxide (IZO), Indium Tin Zinc oxide (ITZO), Tin oxide (SnO), Zinc oxide (ZnO), Indium Copper oxide (ICO) and/or Aluminum:Zinc oxide (AZO).

In one embodiment, the first electrode 210 may have a mono-layer structure of the transparent conductive oxide. In another embodiment, the first electrode 210 may have a bi-layer structure or a triple-layer structure with and further include a reflective layer. In this case, the first electrode 210 may be a reflective electrode.

In one embodiment, the reflective layer may include, but is not limited to, silver (Ag), an alloy including silver (Ag) and at least one of palladium (Pd), copper (Cu), indium (In) and neodymium (Nd), and/or an aluminum-palladium-copper (APC) alloy. For example, the first electrode 210 may have a bi-layer structure of Ag/ITO or APC/ITO or a triple-layer structure of ITO/APC/ITO.

The bank layer 140 is disposed on the planarization layer 130 with covering the periphery of the first electrode 210 correspondingly to the non-emission area NEA. The bank layer 140 exposes or does not cover the center of the first electrode 210 corresponding to the sub-pixel region SP. For example, the bank layer 140 may include a light-blocking material such as a black material, a light-shielding material and/or a light-absorbing material. Alternatively, the bank layer 140 may include a material absorbing specific wavelength ranges.

In another embodiment, the bank layer 140 may have a lamination structure where a color filter includes at least two colorants among a red color filtering material, a green color filtering material, and a blue color filtering material.

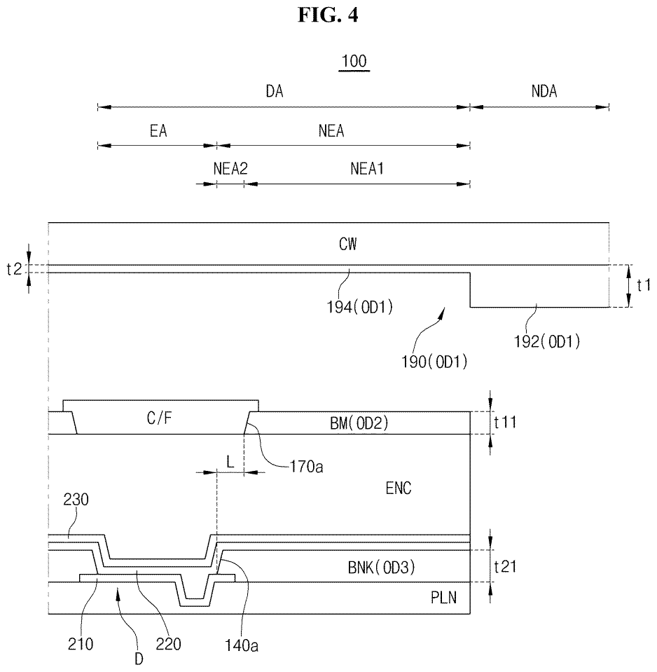

In one embodiment, a side 140a (FIG. 4) of the bank layer 140 that is in contact with an outside of the light-emitting diode D may have a cross-sectional shape inclined downwardly toward the emissive layer 220. In particular, the side 140a of the bank layer 140 may have a cross-sectional shape of which width gradually increases toward the first electrode 210, a tapered cross-sectional shape, but is not limited thereto.

In some embodiments, the side 140a of the bank layer 140 may be curved with a predetermined curvature or may be extended downwardly without the curvature. For example, the side 140a of the bank layer 140 may be disposed with an angle with respect to the surface of the first electrode 210 between about 30° and about 90°, for example, about 450 and about 90°, but is not limited thereto.

A column spacer 144 may be disposed on the bank layer 140. The column spacer 144 may be disposed to surround the emission area EA where the light-emitting diode D is disposed in each sub-pixel region SP. The column spacer 144 may have the same material as the bank layer layer 140. For example, the column spacer 144 may include the light-blocking or light-absorbing material and the binder resin dispersing the light-blocking or light-absorbing material.

For example, the column spacer 144 may have a cross-sectional shape where the width gradually increases toward the bank layer 140 (a trapezoidal cross-sectional shape or a tapered shape), or a cross-sectional shape where the width gradually decreases toward the bank layer 140 (an inverted-trapezoidal cross-sectional shape or an inverted-tapered shape), but is not limited thereto.

The emissive layer 220 is disposed on the first electrode 210. As an example, the emissive layer 220 may have a mono-layer structure of an emitting material layer (EML). The EML may include an organic luminescent material or an inorganic luminescent material. In particular, the light emitting display device 100 may be an organic light emitting display device or an inorganic light emitting display device.

In another embodiment, the emissive layer 220 may have a multi-layer structure. As an example, the emissive layer 142 may further include at least one of a hole injection layer (HIL), a hole transport layer (HTL), an electron blocking layer (EBL), a hole blocking layer (HBL), an electron transport layer (ETL), and an electron injection layer (EIL) in addition to the EML.

The second electrode 230 may be disposed on the substrate 110 onto which the emissive layer 220 is disposed. The second electrode 230 may be disposed on the entire display area and may include a conductive material with relatively low work function value to act as a cathode. For example, the second electrode 230 may include, but is not limited to, aluminum (Al), magnesium (Mg), calcium (Ca), silver (Ag), and alloys thereof such as magnesium silver alloy. The second electrode 230 may have a thin thickness to have a light-transmissive (semi-transmissive) property.

An encapsulation layer (encapsulation film) 150 may be disposed on the second electrode 230 in order to prevent or reduce external oxygen and/or moisture from infiltrating to the light-emitting diode D. In one embodiment, the encapsulation layer 150 may have, but is not limited to, a lamination structure of a first inorganic insulating layer 152, an organic insulating layer 154 and a second inorganic insulating layer 156.

A touch sensor (touch panel) 160 may be disposed on the encapsulation layer 150 to provide a sensing function. As an example, the touch sensor 160 may include a bridge electrode or a connection electrode BRG and a touch electrode 168, and may further include a plurality of insulating layers and/or buffer layers.

In one embodiment, the touch sensor 160 may include a first touch buffer layer 162a, a first touch insulating layer 164a, and a plurality of touch electrodes 166. In addition, the touch sensor 160 may further include a second touch insulating layer 164, an organic touch insulating layer 168a, and a second touch buffer layer 168b covering the touch electrode 166. In some embodiment, the touch sensor 160 may be omitted.

The bridge electrode BRG may be disposed on the first touch buffer layer 162a, and the first touch insulating layer 164a may be disposed to cover the bridge electrode BRG. The second touch insulating layer 164b may be disposed on the first touch insulating layer 164a and the plurality of touch electrodes 166 may be disposed on the first and second touch insulating layers 164a and 164b.

The bridge electrode BRG may be configured to be electrically connected to at least a portion of the plural touch electrodes 166. The first touch insulating layer 164a and the second touch insulating layer 164b may have a contact hole that exposes or do not cover the bridge electrode BRG. In this case, adjacent touch electrodes 166 may be contacted to the bridge electrode BRF through the contact hole to electrically connect to each other.

The first touch insulating layer 164a and the second touch insulating layer 164b may include an inorganic insulating material and/or an organic insulating material. For example, each of the first and second touch insulating layers 164a and 164b may have a multi-layer structure where an organic layer and an inorganic layer are arranged alternately. For example, the first touch insulating layer 164a may include an inorganic insulating material and the second touch insulating layer 164b may include an organic insulating material, but is not limited thereto.

Each of the touch electrodes 166 may be disposed on the first touch insulating layer 164a and the second touch insulating layer 164b corresponding to the non-emission area NEA correspondingly to the bank layer 140 and/or a black matrix 170 to be described later. As the touch electrode 166 may be covered or shielded by the black matrix 170, the touch electrode 166 is not visually recognized from the outside, and thereby minimizing or reducing deterioration in display quality, but the arrangement of the touch electrode 166 is not limited thereto. For example, the touch electrode 168 may include, but is not limited to, a transparent metal oxide as the same as the first electrode 210.

An organic touch insulating layer 168a may be disposed on the touch electrode 166 with covering the entire display area DA of the substrate 110.

A second touch buffer layer 168b may be disposed on the organic touch insulating layer 168a for covering the entire display area DA. The second touch buffer layer 168b is configured to protect the touch sensor 160 when the black matrix 170 and a color filter layer (or color filter pattern) 180 are disposed on the touch senor 160. For example, the second touch buffer layer 168b may include, but is not limited to, an inorganic oxide and/or an inorganic nitride.

The black matrix 170 and the color filter pattern 180 may be disposed on the encapsulation layer 150 or the touch sensor 160. The black matrix 170 and the color filter pattern 180 may minimize or reduce the deterioration of the visibility and contrast ratio of the display device 100 by an external light while maintaining high luminance of light emitted from the light-emitting diode D.

The black matrix 170 may be disposed correspondingly to the non-emission area NEA. The black matrix 170 may have an opening corresponding to the light-emitting diode D. In one embodiment, the black matrix 170 may include a light-blocking material capable of shielding light or absorbing light such as a black resin, a black dye and/or a black pigment. Alternatively or additionally, another color filter layer including a red (R), green (G), and/or blue (B) colorants may be laminated on the black matrix 170.

In one embodiment, the side 140a of the bank layer 140 adjacent to the emission area EA may be further extended toward the emission area EA compared to a side 170a of the black matrix 170 adjacent to the emission area EA by an extension length L (FIG. 4). In particular, a peripheral region of the bank layer 140 which in contact with the light emitting diode D may be further extended to the emission area EA compared to a peripheral region of the black matrix 170 which is in contact with the color filter pattern 180 to have a ‘Pull back’ structure. In the inventive concepts, the term “Pull-back distance” may be used for the separation distance L between the sides 170a adjacent to the emission area EA of the black matrix 170 and the side 140a adjacent to the emission area EA of the bank layer 140. By introducing such a Pull-back structure, viewing angle luminance and color viewing angle properties of the display device 100 may be improved.

An area in which the bank layer 140 and the black matrix 170 are disposed to overlap each other among the non-emission area NEA may be defined as a first non-emission area NEA1 (FIG. 4). An area in which the black matrix 170 is not disposed and only the bank layer 140 is disposed by the Pull-back structure among the non-emission area NEA may be defined as a second non-emission area NEA2 (FIG. 4).

The color filter pattern 180 may be disposed corresponding to the openings, of the black matrix 170. In particular, the color filter pattern 180 may be disposed correspondingly to the emission area EA. When the sub-pixel region SP includes the red sub-pixel, the green sub-pixel and the blue sub-pixel, the color filter layer 180 may include a red color filter pattern corresponding to the red sub-pixel, a green color filter pattern corresponding to the green sub-pixel, and a blue color filter pattern corresponding to the blue sub-pixel.

The red color filter pattern may include at least one of a red dye and a red pigment. The green color filter pattern may include at least one of a green dye and a green pigment. The blue color filter pattern may include at least one of a blue dye and a blue pigment.

A first insulating layer 182 may be disposed on the black matrix 170 and the color filter pattern 180 with covering the entire substrate 110. The first insulating layer 182 may include an inorganic insulating material and/or an organic insulating material. Alternatively or additionally, a second insulating layer may be disposed on the first insulating layer 182.

An auxiliary black matrix 190 may be disposed on the first insulating layer 182 in the display area DA and the non-display area NDA. In one embodiment, an adhesive layer 184 may be interposed between the first insulating layer 182 and the auxiliary black matrix 190. The adhesive layer 184 may include, but is not limited to, an optically clear resin (OCR) or a gray adhesive resin.

A cover window CW may be disposed on the auxiliary black matrix 190. The cover window CW constitutes an outer periphery of the display device 100. The cover window CW may be positioned outside the surface on which the image is displayed on the display panel, transmits the images of the display panel, and protects the display panel from external impact or stress.

The cover window CW may include a reinforced glass and/or a reinforced plastic material. For example, the cover window CW may include, but is not limited to, a material selected from high-strength reinforced glass, polyethylene terephthalate (PET), acrylic resins and/or (meth) acrylate resins such as polymethyl methacrylate (PMMA) to prevent or reduce scratches from the outside.

Black among colors recognized by humans is a color that is sensitively recognized even with a slight change in level. Therefore, it is important to implement a high level of black in relation to black reflection visibility. In accordance with the inventive concepts, a uniform black reflection visibility may be implemented in the entire area on the display surface side of the display device 100.

FIG. 4 is a schematic diagram illustrating components of a bank layer, a black matrix and an auxiliary black matrix with related to an optical density by areas in the display device in accordance with the first embodiment of the inventive concepts.

Referring to FIG. 4, the bank layer BNK may be disposed in the non-emission area NEA on the planarization layer PLN. The auxiliary black matrix 190 may be disposed in the display area DA and the non-display area NDA under the cover window CW. In one embodiment, the upper structure in the display area DA and the non-display area NDA of the display device 100 may be configured identically. Accordingly, a uniform black reflection visibility may be realized in the display area DA and the non-display area NDA adjacent to the display surface of the display device 100. The auxiliary black matrix 190 may include a first auxiliary black matrix 192 positioned in the non-display area NDA and a second auxiliary black matrix 194 positioned in the display area DA. The first auxiliary black matrix 192 has a first thickness t1 and the second auxiliary black matrix has a second thickness t2.

The bank layer BNK is closely disposed with an upper surface of the first electrode 210 and a lower surface of emissive layer 220. The content of the light-blocking material in the bank layer BNK may be relatively small to maintain processability and reliability when patterning the bank layer BNK. The black matrix BM may be disposed adjacently to the color filter pattern C/F. The content of the light-blocking material in the black matrix BM may be limited considering compatibility with the color filter pattern C/F and processability and reliability when patterning the black matrix BM.

On the other hand, issues such as the processability and the reliability are relatively small when the auxiliary black matrix 190 is disposed under the cover window CW. Accordingly, the content of the light-blocking material in the auxiliary black matrix 190 may be relatively greatly increased. The auxiliary black matrix 190, 192 or 194 contains relatively high amount of the light-blocking material so that the auxiliary black matrixes 190, 192 or 194 may have a first optical density OD1 per unit thickness.

The black matrix BM may be disposed in the first non-emission area NEA2 between the encapsulation layer ENC and the second auxiliary black matrix 194. The black matrix BM may have a second optical density OD2 per unit thickness. The second optical density OD2 per unit thickness of the black matrix BM may be lower than the first optical density OD1 per unit thickness of the auxiliary black matrix 190, 192, or 194.

The bank layer BNK may be disposed correspondingly to the non-emission area NEA between the planarization layer PLN and the encapsulation layer ENC. The bank layer BNK may have a third optical density OD3 per unit thickness. The third optical density OD3 per unit thickness of the bank layer BNK may be lower than the first optical density OD1 per unit thickness of the auxiliary black matrix 190, 192, or 194, and the second optical density OD2 per unit thickness of the black matrix BM.

Each of the bank layer BNK, the black matrix BM and the auxiliary black matrix 190 may include the light-blocking material. In one embodiment, the light-blocking material may include a black colorant capable of absorbing light such as a black pigment and/or a black dye, and/or the light-shielding material. For example, the light-blocking material may include, but is not limited to, carbon black, carbon nanotube (CNT), graphene, organic black, a black dye, a perylene-containing material, an azo-containing material, a nano-based carbon material, a hybrid type of red (R)/green (G)/blue (B) pigments/dyes, a multiple thin-film material. In addition, the light-blocking material may include an organic material that may be oxidized and converted to black color in a post-baking process.

Each of the bank layer BNK, the black matrix BM and the auxiliary black matrix 190 may include a binder resin. The binder resin that may be applied in the bank layer BNK, the black matrix BM, and the auxiliary black matrix 190 may be any photosensitive binder resin.

In another embodiment, the planarization layer PLN corresponding to the non-emission area NEA may include the light-blocking material such as the black colorants. In this case, the third optical density OD3 per unit thickness of the bank layer BNK may be lowered by reducing the content of the light-blocking material in the bank layer BNK.

With respect to the black reflection visibility, the second auxiliary black matrix 194 in the display area DA, the black matrix BM, and the bank layer BNK may be overlapped with each other in the first non-emission area NEA1. The second auxiliary black matrix 194 in the display area DA and the bank layer BNK may be overlapped with each other in the second non-emission area NEA2. Only the second auxiliary black matrix 194 in the display area DA may be disposed in the emission area EA in which the light-emitting diode D and the color filter pattern C/F may be disposed with respect to the black reflection visibility.

With respect to the black reflection visibility, the total optical density in each area may be calculated by multiplying the optical density per unit thickness of each component including the light-blocking material such as the black colorant, by the thickness of each component. The total optical density related with the black reflection visibility in the non-display area NDA, the first non-emission area NEA1, the second non-emission area NEA2, and the emission area EA may be calculated by the following Equation 1, Equation 2-2, Equation 3-1, and Equation 4-1, respectively.

$$[ Total Optical Density in NDA ] \qquad ( Equation 1 )$$

$$First optical density OD 1 per unit thickness * first thickness t 1$$

$$[ Total Optical Density in NEA 1 ] \qquad ( Equation 2 - 1 )$$

$$( First optical density OD 1 per unit thickness * second thickness t 2 ) + ( second optical density OD 2 per unit thickness * thickness t 11 ) + ( third optical density OD 3 per unit thickness * thickness t 21 )$$

$$[ Total Optical Density in NEA 2 ] \qquad ( Equation 3 - 1 )$$

$$( First optical density OD 1 per unit thickness * second thickness t 2 ) + ( third optical density OD 3 per unit thickness * thickness t 21 )$$

$$[ Total Optical Density in EA ] \qquad ( Equation 4 - 1 )$$

$$First optical density OD 1 per unit thickness * second thickness t 2$$

The black reflection visibility in each area may be uniformly set by designing the total optical density in each area, such as the non-display area NDA and the second non-emission area NEA2. The optical densities OD1, OD2 and OD3 per unit thickness and the thickness t1, t2, t11, and t12 of the bank layer BNK, the black matrix BM, and the auxiliary black matrix 190 may be adjusted so that the display device 100 may implement uninform black reflection visibility on the display surface in the whole areas.

In one embodiment, the first optical density OD1 per unit thickness of the auxiliary black matrix 190, 192, or 194 may be, but is not limited to, 1.1 times to 2 times, for example, 1.2 times to 1.8 times, the second optical density OD2 per unit thickness of the black matrix BM. In another embodiment, the second optical density OD2 per unit thickness of the black matrix BM may be, but is not limited to, 1.2 times to 2 times, for example, 1.5 times to 1.8 times, the third optical density OD3 per unit thickness of the bank layer BNK. In another embodiment, the first optical density OD1 per unit thickness of the auxiliary black matrix 190, 192 or 194 may be, but is not limited to, 1.3 times to 3 times, for example, 1.5 times to 2 times, the third optical density OD3 per unit thickness of the bank layer BNK.

For example, the first optical density OD1 per 1 μm thickness of the auxiliary black matrix 190, 192, or 194 may be, but is not limited to, about 1.2 to about 2.0. The second optical density OD2 per 1 μm thickness of the black matrix BM may be, but is not limited to, about 1.0 to about 1.5. The third optical density OD3 per 1 μm thickness of the bank layer BNK may be, but is not limited to, about 0.6 to about 1.2.

The first thickness t1 of the first auxiliary black matrix 192 may differ from the thickness t2 of the second auxiliary black matrix 194. In one embodiment, the thickness t1 of the first auxiliary black matrix 192 may be greater than the thickness t2 of the second auxiliary black matrix 194.

With respect to the black reflection visibility, the black matrix BM and/or the bank layer BNK are additionally configured to be disposed in the non-emission area NEA among the display area DA. Even if the thickness t2 of the second auxiliary black matrix 194 is designed to be small compared to the thickness t1 of the first auxiliary black matrix 192, more uniform black reflection visibility may be implemented in the non-display area NDA and the non-emission area NEA.

In one embodiment, the first thickness t1 of the first auxiliary black matrix 192 may be, but is not limited to, about 5 times to about 50 times, for example, about 10 times to about 30 times, the thickness t2 of the second auxiliary black matrix 194. For example, the first thickness t1 of the first auxiliary black matrix 192 may be, but is not limited to, about 1.0 μm to about 4.0 μm, for example, about 1.5 μm to about 3.5 μm or about 2.0 μm to about 3.0 μm. The second thickness t2 of the second auxiliary black matrix 194 may be, but is not limited to, about 0.05 μm to about 0.5 μm, for example, about 0.05 μm to about 0.3 μm or about 0.05 μm to about 0.2 μm.

The thickness t11 of the black matrix BM having the second optical density OD2 per unit thickness may be substantially the same as or greater than the thickness t13 of the bank layer BNK having the third optical density OD3 per unit thickness. In one embodiment, the thickness t11 of the black matrix BM may be 1.0 times to 1.5 times the thickness t21 of the bank layer BNK. For example, each of the thickness t11 of the black matrix BM and the thickness t21 of the bank layer BNK may be, but is not limited to, about 1.0 μm to 3.0 μm.

The auxiliary black matrix 190 may be disposed on the whole upper areas corresponding to the display area DA and the non-display area NDA, and the first to third optical densities OD1, OD2 and OD3 per unit thickness and the thicknesses t1, t2, t11 and th21 of the auxiliary black matrix 190, 192 or 194, the black matrix BM and the bank layer are configured to be adjusted. In the display device 100, the bank layer BNK, the black matrix BM and/or the auxiliary black matrices 190, 192 and 194 having different optical densities OD1, OD2 and OD3 per unit thickness and thicknesses t1, t2, t11, and t21 are disposed in the display area DA and the non-display area NDA, respectively. It is possible to overcome the difference in length of an incident and/or reflected external light path depending on the areas.

The auxiliary black matrices 190, 192 and 194 may be disposed in the display area DA and the non-display area NDA under the cover window CW. In the display area and the non-display area NDA, some of the external light transmitting through the cover window CW may be absorbed by the auxiliary black matrices 190, 192, and 194, and other of the external light not absorbed by the auxiliary black matrices 190, 192, and 194 may be incident and reflected to the display panel or the pad member PAD (FIG. 1) through the same or similar path. More particularly, a uniform amount of the external light may be incident into the display area DA and the non-display area NDA. The external light may be incident and reflected through a similar path in the display area DA and the non-display area NDA so that a deviation of a reflection of the external light depending on the areas may be minimized or reduced. Accordingly, the optical density and light transmittance related to the black reflection visibility may be uniformly set in the non-display area NDA and the non-emission area NEA such as the first non-emission area NEA1, which are areas in which light is not transmitted, among the areas in the display device 100.

In addition, the external light reflected from electrodes or wires formed of metal disposed within the display panel may be absorbed by the bank layer BNK, the black matrix BM and the auxiliary black matrices 190, 192 and 194 each of which may include the light-blocking material. Accordingly, it is possible to minimize or reduce the incidence of the external light to the light-emitting diode D and reflection of the external light from the touch electrode 166, and maximize or improve the re-absorption of the external light in the bank layer BNK, the black matrix BM and the auxiliary black matrices 190, 192 and 194, and thereby preventing or reducing mura caused by the reflection of the external light.

In general, an ambient light diffraction mura due to the step difference caused by the thin film transistor Tr may occur. In addition, as the diffraction of the reflected external light is further enhanced by the color filter layer pattern C/F, a rainbow mura may be occurred or caused by the interference between adjacent sub-pixel regions SPs, the light reflection at the conductive material such as the conductive films and/or electrodes within the display panel, and the refractive index differences between the layers in which the light passes through.

In accordance with the first embodiment, it is possible to prevent or at least suppress the external light from being reflected outside of the display device 100 by disposing the auxiliary black matrix 190, the black matrix BM, and/or the bank layer BNK, in which the optical densities OD1, OD2 and OD3 per unit thickness and the thicknesses t1, t2, t11 and t12 are adjusted. In addition, the content of the light-blocking material in the black matrix BM and the bank layer BNK is not increased. Therefore, the process reliability for the black matrix BM and the bank layer BNK may be secured.

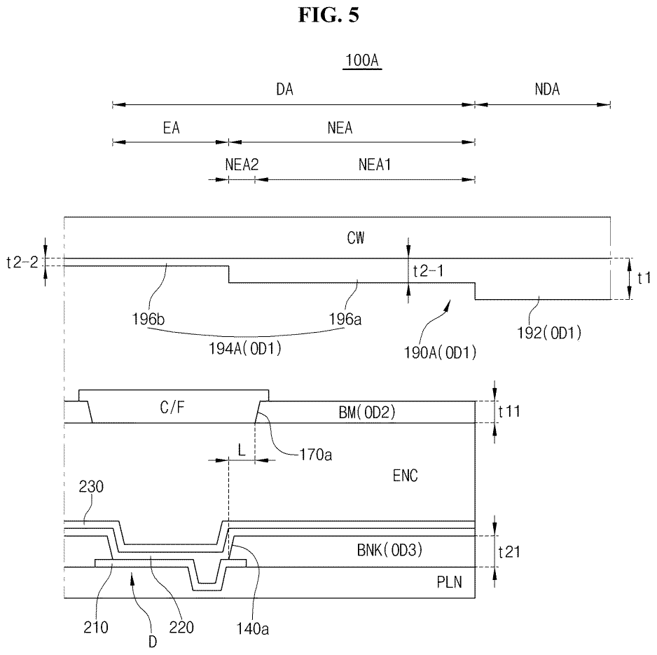

In FIG. 4, the thickness and/or the cross-sectional shape of the second auxiliary black matrix 194 positioned correspondingly to the display area DA is exemplarly illustrated as being uniformly designed. In another embodiment, the thickness and the cross-sectional shape of the second auxiliary black matrix may be variously modified. FIGS. 5 to 9 are schematic diagrams illustrating components of the bank layer, the black matrix and the auxiliary black matrix in the display device in accordance with various other embodiments of the inventive concepts.

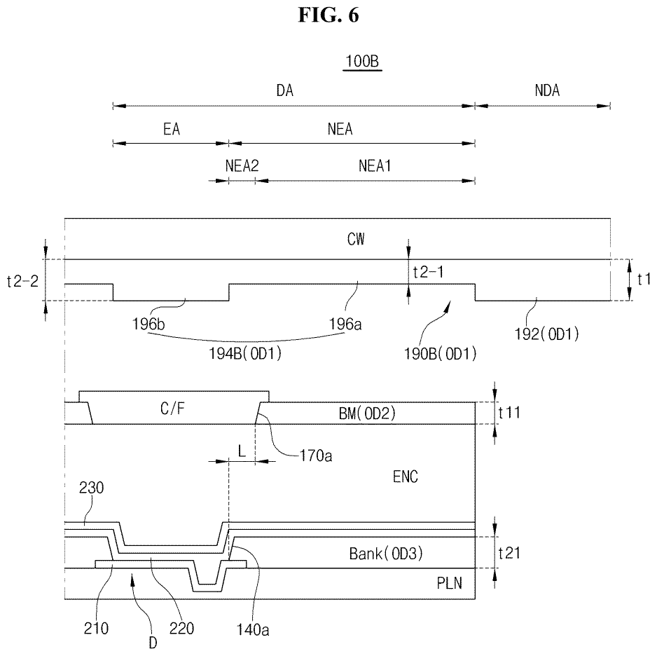

Referring to FIG. 5, the auxiliary black matrix 190A is shown as being disposed under the cover window CW, which constitutes the outmost portion of the display device 100A, and in which the display device 100A includes the first auxiliary black matrix 192 positioned correspondingly to the non-display area NDA and a second auxiliary black matrix 194A positioned correspondingly to the display area DA. Referring to FIG. 6, the auxiliary black matrix 190B is disposed under the cover window CW, which constitutes the outmost portion of the display device 100B, which includes the first auxiliary black matrix 192 positioned correspondingly to the non-display area NDA, and a second auxiliary black matrix 194B positioned correspondingly to the display area DA. In FIGS. 5 and 6, the first thickness t1 of the first auxiliary black matrix 192 may be greater than a second thickness t2-1 or t2-2 of the second auxiliary black matrix 194A or 194B.

The second auxiliary black matrices 194A and 194B may include a third auxiliary black matrix 196a positioned correspondingly to the non-emission area NEA and a fourth auxiliary black matrix 196b positioned correspondingly to the emission area EA. As illustrated in FIG. 5, a third thickness t2-1 of the third auxiliary black matrix 196a may be greater than a fourth thickness t2-2 of the fourth auxiliary black matrix 196b. As illustrated in FIG. 6, the fourth thickness t2-2 of the fourth auxiliary black matrix 196b may be greater than the third thickness 2-1 of the third auxiliary black matrix 196a.

The total optical density in relation with the black reflection visibility in the first non-emission area NEA1, the second non-emission area NEA2 and the emission area EA of the display device 100A or 100B may be calculated by the following Equation 2-2, Equation 3-2, and Equation 4-2, respectively.

$$[ Total Optical Density in NEA 1 ] \qquad ( Equation 2 - 2 )$$

$$( First optical density OD 1 per unit thickness * third thickness t 2 - 1 ) + ( second optical density OD 2 per unit thickness * thickness t 11 ) + ( third optical density OD 3 per unit thickness * thickness t 21 )$$

$$[ Total Optical Density in NEA 2 ] \qquad ( Equation 3 - 2 )$$

$$( First optical density OD 1 per unit thickness * third thickness t 2 - 1 ) + ( third optical density OD 3 per unit thickness * thickness t 21 )$$

$$[ Total Optical Density in EA ] \qquad ( Equation 4 - 2 )$$

$$First optical density OD 1 per unit thickness * fourth thickness t 2 - 2$$

With reference to FIG. 5, the luminance in the emission area EA may be improved by designing the fourth thickness t2-2 of the fourth auxiliary black matrix 196b to be smaller than the third thickness t2-1 of the third auxiliary black matrix 196a. With reference to FIG. 6, the black reflection visibility in the emission area EA may be implemented close to the black reflection visibility in the non-emission area NEA by designing the fourth thickness t2-2 of the fourth auxiliary black matrix 196b to be greater than the third thickness t2-1 of the third auxiliary black matrix 196a.

The first thickness t1 of the first auxiliary black matrix 192 may be about 5 times to about 50 times, for example, about 10 times to about 30 times, the second thickness t2-1 or t2-2 of the second auxiliary black matrix 194A or 194B. The first thickness t1 of the first auxiliary black matrix 192 may be the same with reference to FIG. 4, and the second thickness t2-1 or t-2 of the second auxiliary black matrix 194A or 194B may be the same as the second thickness t2 of the second auxiliary black matrix 194 with reference to FIG. 4.

With reference to FIG. 5, the fourth thickness t2-2 of the fourth auxiliary black matrix 196b positioned correspondingly to the emission area EA may be about 1/10 to about 9/10, for example, about ⅕ to about ⅘, about ¼ to about ¾ or about ⅓ to about 2/2, of the third thickness t2-1 of the third auxiliary black matrix 196a positioned correspondingly to the non-emission area NEA.

With reference to FIG. 6, the fourth thickness t2-2 of the fourth auxiliary black matrix 196b may be designed so that the luminance of light transmitted through the fourth auxiliary black matrix 196b positioned correspondingly to the emission area EA may be 50% or more compared to the luminance of light emitted from the light-emitting diode D. For example, the fourth thickness t2-2 of the fourth auxiliary black matrix 196b positioned correspondingly to the emission area EA may be about 1.5 times to about 5 times, for example, about 1.5 times to 3 times, than the third thickness t2-1 of the third auxiliary black matrix 196a positioned correspondingly to the non-emission area NEA in FIG. 6.

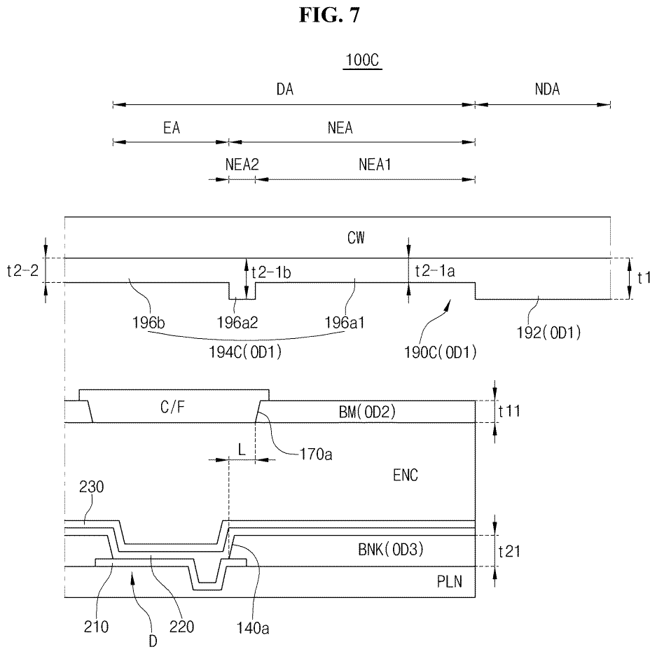

With reference to FIG. 7, the auxiliary black matrix 190C disposed under the cover window CW is configured to constitute the outmost portion of the display device 100C, in which the display device 100C includes the first auxiliary black matrix 192 positioned correspondingly to the non-display area NDA and a second auxiliary black matrix 194C positioned correspondingly to the display area DA. The first thickness t1 of the first auxiliary black matrix 192 may be greater than the second thickness t2-1, t2-1b or t2-2 of the second auxiliary black matrix 194C.

The second auxiliary black matrix 194C may include a third auxiliary black matrix 196a1 positioned correspondingly to the first non-emission area NEA1, a fifth auxiliary black matrix 196a2 positioned correspondingly to the second non-emission area NEA2, and a fourth auxiliary black matrix 196b positioned correspondingly to the emission area EA. A fifth thickness t2-1b of the fifth auxiliary black matrix 196a2 may be designed to be greater than the third thickness t2-1a of the third auxiliary black matrix 196a1 and/or the fourth thickness t2-2 of the fourth auxiliary black matrix 196b.

The total optical density in relation with the black reflection visibility in the first non-emission area NEA1, the second non-emission area NEA2 and the emission area EA of the display device 100C may be calculated by the following Equation 2-3, Equation 3-3, and Equation 4-3, respectively.

$$[ Total Optical Density in NEA 1 ] \qquad ( Equation 2 - 3 )$$

$$( First optical density OD 1 per unit thickness * third thickness t 2 - 1 a ) + ( second optical density OD 2 per unit thickness * first thickness t 11 ) + ( third optical density OD 3 per unit thickness * t hickness t 21 )$$

$$[ Total Optical Density in NEA 2 ] \qquad ( Equation 3 - 3 )$$

$$( First optical density OD 1 per unit thickness * fifth thickness t 2 - 1 b ) + ( third optical density OD 3 per unit thickness * thickness t 21 )$$

$$[ Total Optical Density in EA ] \qquad ( Equation 4 - 3 )$$

$$First optical density OD 1 per unit thickness * fourth thickness t 2 - 2$$

In the display device 100C illustrated in FIG. 7, the fifth thickness t2-1b of the fifth auxiliary black matrix 196a2 positioned correspondingly to the second non-emission area NEA2 may be designed to be relatively great. In this manner, it is possible to implement the black reflection visibility in the second non-emission area NEA2 close to the black reflection visibility in the first non-emission area NEA1.

The first thickness t1 of the first auxiliary black matrix 192 may be about 5 times to about 50 times, for example, about 10 times to about 30 times, the second thickness t2-1a, t2-1b, or t2-2 of the second auxiliary black matrix 194C. The first thickness t1 of the first auxiliary black matrix 192 may be the same with reference to FIG. 4, and the second thickness t2-1a, t2-1b or t2-2 of the second auxiliary black matrix 194C may be the same as the second thickness t2 of the second auxiliary black matrix 194 with reference to FIG. 4. The fifth thickness t2-1b of the fifth auxiliary black matrix 196a2 positioned correspondingly to the second non-emission area NEA2 may be about 1.5 times to about 5 times, for example, about 1.5 times to 3 times, than the third thickness t2-1a of third auxiliary black matrix 196a1 positioned correspondingly to the first non-emission area NEA1 and/or the fourth thickness t2-2 of the fourth auxiliary black matrix 196b positioned correspondingly to the emission area EA.

In FIG. 7, the third thickness t2-1a of the third auxiliary black matrix 196a1 is exemplarily illustrated as being substantially the same as the fourth thickness t2-2 of the fourth auxiliary black matrix 196b. In another embodiment, the third thickness t2-1a of the third auxiliary black matrix 196a1 positioned correspondingly to the first non-emission area NEA1 may be greater, as illustrated in FIG. 5, or smaller, as illustrated in FIG. 6, than the fourth thickness t2-2 of the fourth auxiliary black matrix 196b positioned correspondingly to the emission area EA.

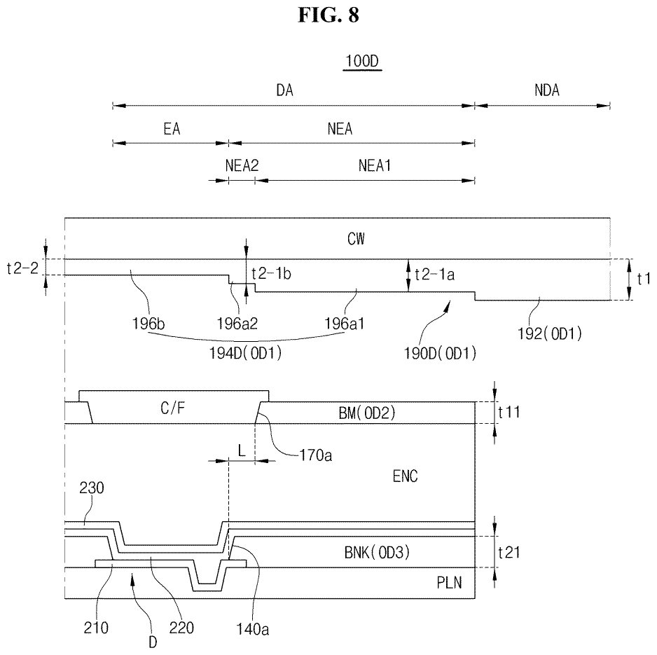

With reference to FIG. 8, the auxiliary black matrix 190D disposed under the cover window CW is configured to constitute the outmost portion of the display device 100D, in which the display device 100D may include the first auxiliary black matrix 192 positioned correspondingly to the non-display area NDA, and the second auxiliary black matrix 194D positioned correspondingly to the display area DA. The first thickness t1 of the first auxiliary black matrix 192 may be greater than the second thickness t2-1a, t2-1b, or t2-2 of the second auxiliary black matrix 194D.

The second auxiliary black matrix 194D may include a third auxiliary black matrix 196a1 positioned correspondingly to the first non-emission area NEA1, a fifth auxiliary black matrix 196a2 positioned correspondingly to the second non-emission area NEA2, and a fourth auxiliary black matrix 196b positioned correspondingly to the emission area EA. In this embodiment, the third thickness t2-1a of the third auxiliary black matrix 196a1 may be greater than the fifth thickness t2-1b of the fifth auxiliary black matrix 196a2. The fifth thickness t2-1b of the fifth auxiliary black matrix 196a2 may be greater than the fourth thickness t2-2 of the fourth auxiliary black matrix 196b.

The total optical density with regard to the black reflection visibility in the first non-emission area NEA1, the second non-emission area NEA2 and the emission area EA of the display device 100D illustrated in FIG. 8 may be calculated by the Equation 2-3, the Equation 3-3, and Equation 4-3 referring to FIG. 7, respectively.

The first thickness t1 of the first auxiliary black matrix 192 may be about 5 times to about 50 times, for example, about 10 times to about 30 times, the second thickness t2-1a, t2-1b or t2-2 of the second auxiliary black matrix 194D. The first thickness t1 of the first auxiliary black matrix 192 may be the same with reference to FIG. 4, and the second thickness t2-1a, t2-1b or t2-2 of the second auxiliary black matrix 194D may be the same as the second thickness t2 of the second auxiliary black matrix 194 with reference to FIG. 4.

The fifth thickness t2-1b of the fifth auxiliary black matrix 196a2 positioned correspondingly to the second non-emission area NEA2 may be about 1/10 to about 9/10, for example, about ⅕ to about ⅘, about ¼ to about ¾ or about ⅓ to about ½ of the third thickness t2-1a of the third auxiliary black matrix 196a1 positioned correspondingly to the first non-emission area NEA1. The fourth thickness t2-2 of the fourth auxiliary black matrix 196b positioned correspondingly to the emission area EA may be about 1/10 to about 9/10, for example, about ⅕ to about ⅘, about ¼ to about ¾ or about ⅓ to about ½ of the fifth thickness t2-1b of the fifth auxiliary black matrix 196a2 positioned correspondingly to the second non-emission area NEA2.

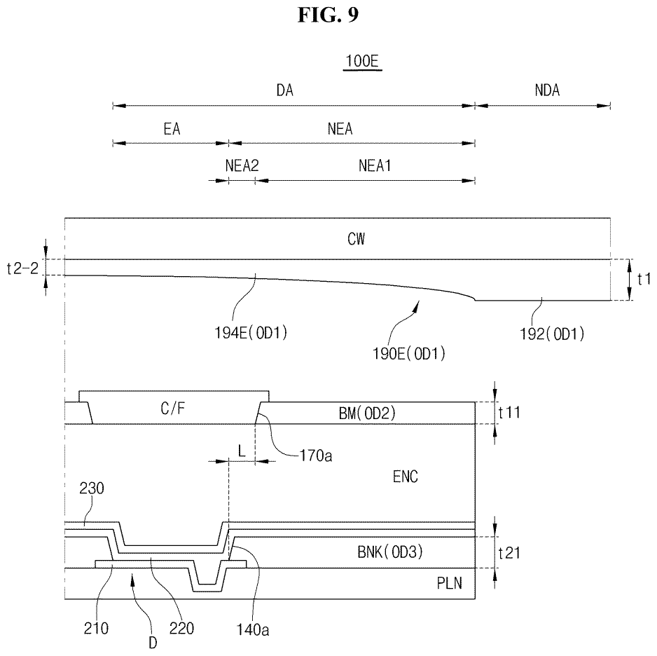

With reference to FIG. 9, the auxiliary black matrix 190E disposed under the cover window CW is configured to constitute the outmost portion of the display device 100E, in which the display device 100E may include the first auxiliary black matrix 192 positioned correspondingly to the non-display area NDA, and the second auxiliary black matrix 194E positioned correspondingly to the display area DA. The first thickness t1 of the first auxiliary black matrix 192 may be greater than the second thickness t2-2 of the second auxiliary black matrix 194E. The second auxiliary black matrix 194E may be configured such that the second thickness t2-2 gradually decreases from the first non-emission area NEA1 to the emission area EA via the second non-emission area NEA2.

In embodiments illustrated in FIGS. 8 and 9, the black reflection visibility on the display surface of the display device 100D or 100E may be gradually changed toward the first non-emission area NEA1, the second non-emission area NEA2, and the emission area EA. Accordingly, more uniform black reflection visibility may be implemented in the entire areas of the display devices 100D and 100E. In addition, as illustrated in FIG. 9, when the second thickness t2-2 of the second auxiliary black matrix 194E is arranged to have a gradual gradient cross-section, irregular reflection of the external light that may be caused in each area may be prevented or reduced.

### Second Embodiment

FIG. 10 illustrates a cross-sectional view taken along line III-III′ shown in FIG. 1 and illustrates a schematic cross-sectional view of a display device in accordance with a second embodiment of the inventive concepts.

Referring to FIG. 10, a display device 300 may include a substrate 310 having the non-display area NDA and the display area DA, which includes the emission area EA and the non-emission area NEA, the light-emitting diode D disposed on the substrate 310 corresponding to the emission area EA, a bank layer 340 disposed on the substrate 310 corresponding to the non-emission area NEA, a black matrix 370 disposed on the bank layer 340 corresponding to the non-emission area NEA, a color filter pattern 380 disposed on the light-emitting diode D corresponding to the emission area EA, and an auxiliary black matrix 390 disposed on the black matrix 370 and the color filter pattern 380.

The substrate 310 defines the sub-pixel region SP (FIG. 2) including the red sub-pixel region, the green sub-pixel region, the blue sub-pixel region, and optionally, the white sub-pixel region.

The thin film transistor Tr may be disposed on the substrate 310. The thin film transistor Tr includes a semiconductor layer 312, a gate electrode 316, a source electrode 320, and a drain electrode 322. The thin film transistor Tr may be the driving thin film transistor Td (FIG. 2).

The semiconductor layer 312 may be disposed directly on the substrate 301 or may be disposed on the buffer layer that may be disposed on the substrate 310. For example, the semiconductor layer 312 may include, but is not limited to, the oxide semiconductor.

A gate insulating layer 314 may be disposed on the semiconductor layer 312 with covering the entire substrate 310. The gate electrode 316 including a conductive material may be disposed on the gate insulating layer 314 corresponding to the center of the semiconductor layer 312. The gate insulating layer 314 may be patterned to have a shape conforming to the gate electrode 316.

An interlayer insulating layer 318 may be disposed on the gate electrode 316. The interlayer insulating layer 318 may have first and second semiconductor contact holes 319a and 319b that expose or do not cover both sides of the semiconductor layer 312. The first and second semiconductor contact holes 319a and 319b are spaced apart from the gate electrode 316 at both sides of the gate electrode 316.

The source electrode 320 and the drain electrode 322 which includes a conductive material such as metal component, may be disposed on the interlayer insulating layer 3180. The source electrode 320 and the drain electrode 322 may be spaced apart from each other with centering the gate electrode 316, and contact to both sides of the semiconductor layer 312 through the first and second semiconductor contact holes 319a and 319b.

A planarization layer 330 may be disposed on the source electrode 320 and the drain electrode 322 with covering the entire substrate 310. The planarization layer 330 may have a contact hole 332 that exposes or do not cover the source electrode 320 or the drain electrode 322.

The light-emitting diode D may include a first electrode 410 disposed on the planarization layer 330 and connected to the source electrode 320 or the drain electrode 322, and an emissive layer 420 and a second electrode 430 that are laminated sequentially on the first electrode 410.

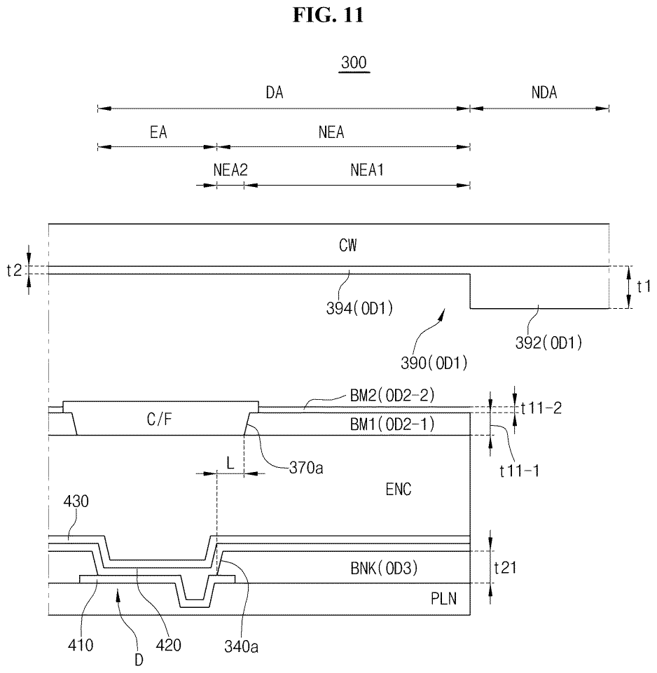

The bank layer 340 may be disposed on the planarization layer 330 corresponding to the non-emission area NEA. In one embodiment, a side 340a (FIG. 11) of the bank layer 340 may be in contact with the light-emitting diode D. The side 340a of the bank layer 340 may have, but is not limited to, a tapered cross-section. A column spacer 344 may be disposed on the bank layer 340. The column spacer 344 may have, but is not limited to, a tapered or an inverted tapered shape.

An encapsulation layer 350 may be disposed on the second electrode 430. The encapsulation layer 350 may have, but is not limited to, a lamination structure of a first inorganic insulating layer 352, an organic insulating layer 354 and a second inorganic insulating layer 356.

A touch sensor 360 may be disposed on the encapsulation layer 350. In one embodiment, the touch sensor 360 may include a first touch buffer layer 362a, a bridge electrode BRG disposed on the first touch buffer layer 362 corresponding to the non-emission area NEA, a first touch insulating layer 364a disposed on the bridge electrode BRG, a second touch insulating layer 364b disposed on the first touch insulating layer 364a, and a plurality of touch electrodes 366 disposed on the second touch insulating layer 364b corresponding to the non-emission area NEA. The touch sensor 360 may further include an organic insulating layer 368a disposed on the touch electrode 366 and a second touch buffer layer 368b disposed on the organic insulating layer 368a.

The black matrix 370 may be disposed on the encapsulation layer 350 or the touch sensor 360 corresponding to the non-emission area NEA. In the second embodiment, the black matrix 370 may include a first black matrix 372 disposed on the encapsulation layer 350 or the touch sensor 360 corresponding to the non-emission area NEA, and a second black matrix 374 disposed on the first black matrix 372 corresponding to the non-emission area NEA.

The color filter pattern 380 may be disposed on the encapsulation layer 350 or the touch sensor 360 corresponding to the emission area EA. The colorant included in the color filter pattern 380 may have different refractive indices depending on wavelengths, and light emitted from the light-emitting diode D may be scattered while passing through the color filter pattern 380 and spread in all directions.

The light exceeding a specific viewing angle should be absorbed by the black matrix 370 in order to implement a high contrast ratio. In the second embodiment of the inventive concepts, the first black matrix 372 and the second black matrix 374 may be sequentially disposed correspondingly to the non-emission area NEA to implement a high contrast ratio, and the display device 300 having further improved viewing angle properties may be implemented.

In one embodiment, after the first black matrix 372 is formed, the color filter pattern 380 and the second black matrix 374 may be sequentially formed. In this case, a part of the colorant used for forming the color filter pattern 380 may be retained in the first black matrix 372. As such, the second black matrix 374 may be disposed to shield the colorant used for forming the color filter pattern 380. The light passing through the first black matrix 372 and/or the color filter pattern 380 may be additionally blocked by the second black matrix 374, such that the viewing angle properties of the display device 300 may be further improved.

A first insulating layer 382 may be disposed on the black matrix 370 and the color filter pattern 380, and a second insulating layer may be disposed on the first insulating layer 382. The auxiliary black matrix 390 may be disposed on the first insulating layer 382 in the display area DA and the non-display area NDA. In one embodiment, an adhesive layer 384 may be interposed between the first insulating layer 382 and the auxiliary black matrix 390. The cover window CW may be disposed on the auxiliary black matrix 390.

FIG. 11 is a schematic diagram illustrating components of a bank layer, a black matrix, and an auxiliary black matrix with related to an optical density by areas in the display device in accordance with the second embodiment of the inventive concepts.

Referring to FIG. 11, the first thickness t1 of the first auxiliary black matrix 392 positioned correspondingly to the non-display area NDA may be greater than the second thickness t2 of the second auxiliary black matrix 394 positioned correspondingly to the display area DA. The auxiliary black matrices 390, 392, and 394 may have the first optical density OD1 per unit thickness.

The first black matrix BM1 and the second black matrix BM2 corresponding to the non-emission area NEA between the encapsulation layer ENC and the second auxiliary black matrix 394 may be disposed sequentially. Both the first black matrix BM1 and the second black matrix BM2 may be disposed in the first non-emission area NE1. The first black matrix BM1 may have a second optical density OD2-1 per unit thickness and the second black matrix BM2 may have a second optical density OD2-2 per unit thickness.

In one embodiment, the second optical density OD2-1 per unit thickness of the first black matrix BM1 may be substantially the same as the second optical density OD2-2 per unit thickness of the second black matrix BM2. Each of the second optical density OD2-1 per unit thickness of the first black matrix BM1 and the second optical density OD2-2 per unit thickness of the second black matrix BM2 may be lower than the first optical density OD1 per unit thickness of the auxiliary black matrices 390, 392, and 394.

The bank layer BNK may be disposed correspondingly to the non-emission area NEA between the planarization layer PLN and the encapsulation layer ENC. The bank layer BNK may have the third optical density OD3 per unit thickness. The third optical density OD3 per unit thickness of the bank layer BNK may be lower than the first optical density OD1 per unit thickness of the auxiliary black matrices 390, 392, and 394, the second optical density OD2-1 per unit thickness of the first black matrix BM1, and the second optical density OD2-2 per unit thickness of the second black matrix BM2.

In one embodiment, the side 340a of the bank layer 340 outside of the light-emitting diode D, for example, which is in contact with the emissive layer 420 may be further extended to the emission area EA by the Pull-back length L compared to a side 370a of the first and second black matrices 372 and 374, each of which is in contact with the outside of the color filer pattern C/F.

With respect to the black reflection visibility, the first auxiliary black matrix 392 may be positioned in the non-display area NDA. The second auxiliary black matrix 394 in the display area DA, the first black matrix BM1, the second black matrix BM2, and the bank layer BNK may be overlapped with each other in the first non-emission area NEA1. The second auxiliary black matrix 394 in the display area DA and the bank layer BNK may be overlapped with each other in the second non-emission area NEA2. Only the second auxiliary black matrix 394 in the display area DA is configured to be disposed in the emission area EA in which the light-emitting diode D and the color filter pattern C/F are disposed with respect to the black reflection visibility.

The total optical density related with the black reflection visibility in the non-display area NDA may be calculated by the Equation 1 referring to FIG. 4. The total optical density related with the black reflection visibility in the first non-emission area NEA1, the second non-emission area NEA2 and the emission area EA may be calculated by the following Equation 2-4, Equation 3-4, and Equation 4-4, respectively.

$$[ Total Optical Density in NEA 1 ] \qquad ( Equation 2 - 4 )$$

$$( First optical density OD 1 per unit thickness * second thickness t 2 ) + ( second optical density OD 2 - 1 per unit thickness * thickness t 11 - 1 ) + ( second optical density OD 2 - 2 * thickness t 11 - 2 ) + ( third optical density OD 3 per unit thickness * thickness t 21 )$$

$$[ Total Optical Density in NEA 2 ] \qquad ( Equation 3 - 4 )$$

$$( First optical density OD 1 per unit thickness * second thickness t 2 ) + ( third optical density OD 3 per unit thickness * thickness t 21 )$$

$$[ Total Optical Density in EA ] \qquad ( Equation 4 - 4 )$$

$$First optical density OD 1 per unit thickness * second thickness t 2$$

The first optical density OD1 per unit thickness of the auxiliary black matrices 390, 392, and 394, and the third optical density OD3 per unit thickness of the bank layer BNK may be the same referring to FIG. 4. The second optical density OD2-1 per unit thickness of the first black matrix BM1 and the second optical density OD2-2 per unit thickness of the second black matrix BM2 may be the same as the second optical density OD2 of the black matrix BM referring to FIG. 4.

The first thickness t1 of the first auxiliary black matrix 392 positioned correspondingly to the non-display area NDA may be greater than the second thickness t2 of the second auxiliary black matrix 394 positioned correspondingly to the display area DA. The first thickness t1 of the first auxiliary black matrix 392 and the second thickness t2 of the second auxiliary black matrix 394 may be the same referring to FIG. 4.

In one embodiment, the sum of the thickness t11-1 of the first black matrix BM1 having the second optical density OD2-1 per unit thickness and the thickness t11-2 of the second black matrix BM2 having the second optical density OD2-2 per unit thickness may be substantially the same as the thickness t11 of the black matrix BM referring to FIG. 4. In one embodiment, the first black matrix BM1 may have the thickness t11-1 equal to more than the thickness t11-2 of the second black matrix BM2. In this case, the viewing angle properties of the display device 300 may be further improved.

In another embodiment, the sum of the thickness t11-1 of the first black matrix BM1 having the second optical density OD2-1 per unit thickness and the thickness t11-2 of the second black matrix BM2 having the second optical density OD2-2 per unit thickness may be substantially the same as or greater than the thickness t12 of the bank layer BNK having the third optical density OD3 per unit thickness.

According to embodiments, it is possible to overcome the difference in length of an incident and/or reflected external light path depending on the areas. The external light is configured to be incident and reflected through a similar path in the display area DA and the non-display area NDA so that a deviation of a reflection of the external light depending on the areas may be minimized or reduced. The optical density and light transmittance related to the black reflection visibility may be uniformly set in the non-display area NDA and the non-emission area NEA such as the first non-emission area NEA1, which are areas that may not transmit, among the areas in the display device 300. The uniform black reflection visibility in the whole areas of the display surface of the display device 300 may be implemented. The re-absorption of the external light in the bank layer BNK, the first black matrix BM1, the second black matrix BM2, and the auxiliary black matrices 390, 392 and 394 is improved, so that the reflection of the external light and the stains caused by the reflection of the external light may be minimized or reduced.

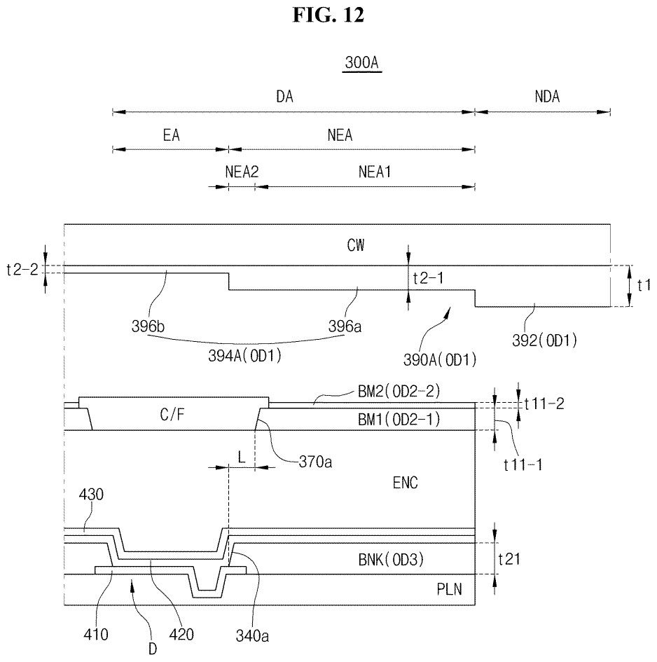

In another embodiment, the thickness and the cross-sectional shape of the second auxiliary black matrix may be variously modified. FIGS. 12 to 16 are schematic diagrams illustrating components of the bank layer, the black matrix, and the auxiliary black matrix in the display device in accordance with various other embodiments of the inventive concepts.

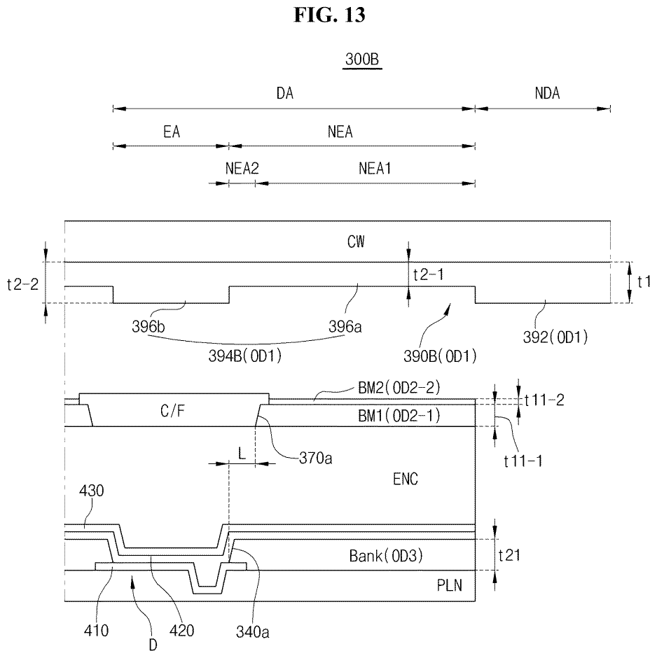

Referring to FIG. 12, the auxiliary black matrix 390A may be disposed under the cover window CW constituting the outmost of the display device 300A, in which the display device 300A includes the first auxiliary black matrix 392 positioned correspondingly to the non-display area NDA and a second auxiliary black matrix 394A positioned correspondingly to the display area DA. Referring to FIG. 13, the auxiliary black matrix 390B may be disposed under the cover window CW constituting the outmost of the display device 300B, in which the display device 300B includes the first auxiliary black matrix 392 positioned correspondingly to the non-display area NDA, a second auxiliary black matrix 394B correspondingly to the display area DA. In FIGS. 12 and 13, the first thickness t1 of the first auxiliary black matrix 392 may be greater than a second thickness t2-1 or t2-2 of the second auxiliary black matrix 394A or 394B.

In FIGS. 12 and 13, the second auxiliary black matrices 394A and 394B may include a third auxiliary black matrix 396a positioned correspondingly to the non-emission area NEA and a fourth black matrix 396b positioned correspondingly to the emission area EA. As illustrated in FIG. 12, a third thickness t2-1 of the third auxiliary black matrix 396a may be greater than a fourth thickness t2-2 of the fourth auxiliary black matrix 396b. As illustrated in FIG. 6, the fourth thickness t2-2 of the fourth auxiliary black matrix 396b may be greater than the third thickness 2-1 of the third auxiliary black matrix 396a.

The total optical density in relation with the black reflection visibility in the first non-emission area NEA1, the second non-emission area NEA2 and the emission area EA of the display device 100A or 100B may be calculated by the following Equation 2-5, Equation 3-5, and Equation 4-5, respectively.

$$[ Total Optical Density in NEA 1 ] \qquad ( Equation 2 - 5 )$$

$$( First optical density OD 1 per unit thickness * third thickness t 2 - 1 ) + ( second optical density OD 2 - 1 per unit thickness * thickness t 11 - 1 ) + ( second optical density OD 2 - 2 per unit thickness * thickness t 11 - 2 ) + ( third optical density OD 3 per unit thickness * thickness t 21 )$$

$$[ Total Optical Density in NEA 2 ] \qquad ( Equation 3 - 5 )$$

$$( First optical density OD 1 per unit thickness * third thickness t 2 - 1 ) + ( third optical density OD 3 per unit thickness * thickness t 21 )$$

$$[ Total Optical Density in EA ] \qquad ( Equation 4 - 5 )$$

$$First optical density OD 1 per unit thickness * fourth thickness t 2 - 2$$

The first thickness t1 of the first auxiliary black matrix 392, the third thickness t2-1 of the third auxiliary black matrix 396a positioned correspondingly to the non-emission area NEA, and the fourth thickness t2-2 of the fourth auxiliary black matrix 396b illustrated in FIGS. 12, and 13 may be the same with reference to FIGS. 5 and 6.

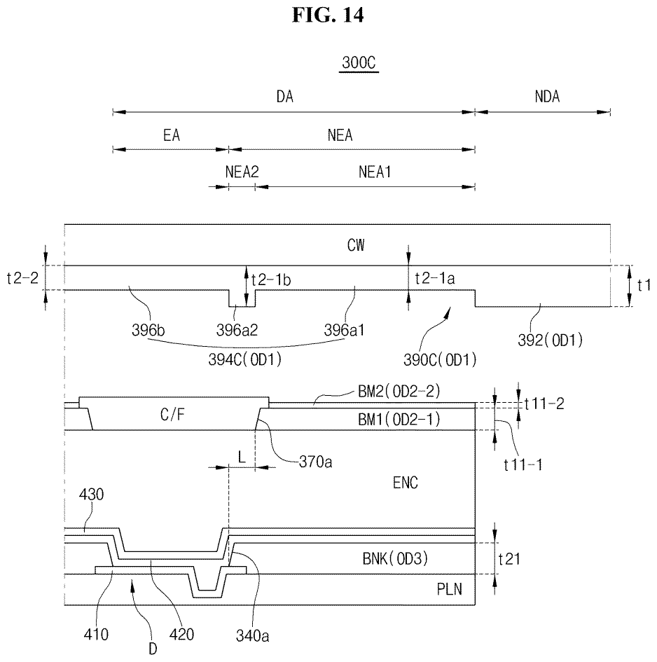

With reference to FIG. 14, the auxiliary black matrix 390C may be disposed under the cover window CW constituting the outmost of the display device 300C, in which the display device 300C includes the first auxiliary black matrix 392 positioned correspondingly to the non-display area NDA and a second auxiliary black matrix 394C positioned correspondingly to the display area DA. The first thickness t1 of the first auxiliary black matrix 392 may be greater than the second thickness t2-1, t2-1b, or t2-2 of the second auxiliary black matrix 394C.

The second auxiliary black matrix 394C may include a third auxiliary black matrix 396a1 positioned correspondingly to the first non-emission area NEA1, a fifth auxiliary black matrix 396a2 positioned correspondingly to the second non-emission area NEA2, and a fourth auxiliary black matrix 396b positioned correspondingly to the emission area EA. A fifth thickness t2-1b of the fifth auxiliary black matrix 396a2 may be designed to be greater than the third thickness t2-1a of the third auxiliary black matrix 396a1 and/or the fourth thickness t2-2 of the fourth auxiliary black matrix 396b.

The total optical density in relation with the black reflection visibility in the first non-emission area NEA1, the second non-emission area NEA2, and the emission area EA of the display device 300C may be calculated by the following Equation 2-6, Equation 3-6 and Equation 4-6, respectively.

$$[ Total Optical Density in NEA 1 ] \qquad ( Equation 2 - 6 )$$

$$( First optical density OD 1 per unit thickness * third thickness t 2 - 1 a ) + ( second optical density OD 2 - 1 per unit thickness * thickness t 11 - 1 ) + ( second optical density OD 2 - 2 per unit thickness * thickness t 11 - 2 ) + ( third optical density OD 3 per unit thickness * thickness t 21 )$$

$$[ Total Optical Density in NEA 2 ] \qquad ( Equation 3 - 6 )$$

$$( First optical density OD 1 per unit thickness * fifth thickness t 2 - 1 b ) + ( third optical density OD 3 per unit thickness * thickness t 21 )$$

$$[ Total Optical Density in EA ] \qquad ( Equation 4 - 6 )$$

$$First optical density OD 1 per unit thickness * fourth thickness t 2 - 2$$

The first thickness t1 of the first auxiliary black matrix 392, the third thickness t2-1a of the third auxiliary black matrix 396a1 positioned correspondingly to the first non-emission area NEA1, the fifth thickness t2-1b of the fifth auxiliary black matrix 396a2 positioned correspondingly to the second non-emission area NEA2, and the fourth thickness t2-2 of the fourth auxiliary black matrix 396b positioned correspondingly to the emission area EA may be the same with reference to FIG. 7.

In FIG. 14, the third thickness t2-1a of the third auxiliary black matrix 396a1 is configured to be substantially the same as the fourth thickness t2-2 of the fourth auxiliary black matrix 396b. In another embodiment, the third thickness t2-1a of the third auxiliary black matrix 396a1 positioned correspondingly to the first non-emission area NEA1 may be greater, as illustrated in FIG. 12, or smaller, as illustrated in FIG. 13, than the fourth thickness t2-2 of the fourth auxiliary black matrix 396b positioned correspondingly to the emission area EA.

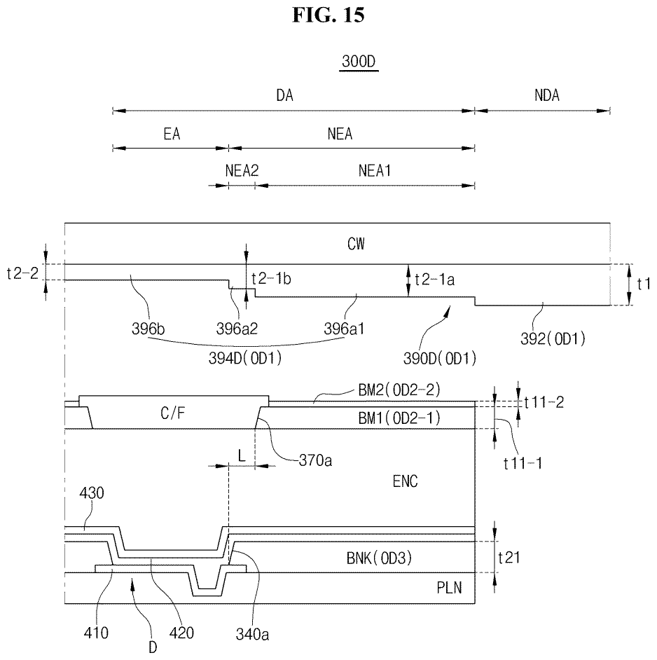

With reference to FIG. 15, the auxiliary black matrix 390D may be disposed under the cover window CW constituting the outmost of the display device 300D, in which the display device 300D includes the first auxiliary black matrix 392 positioned correspondingly to the non-display area NDA, and the second auxiliary black matrix 394D positioned correspondingly to the display area DA. The first thickness t1 of the first auxiliary black matrix 392 may be greater than the second thickness t2-1a, t2-1b or t2-2 of the second auxiliary black matrix 394D.

The second auxiliary black matrix 394D may include a third auxiliary black matrix 396a1 positioned correspondingly to the first non-emission area NEA1, a fifth auxiliary black matrix 396a2 positioned correspondingly to the second non-emission area NEA2, and a fourth auxiliary black matrix 396b positioned correspondingly to the emission area EA. In this embodiment, the third thickness t2-1a of the third auxiliary black matrix 396a1 positioned correspondingly to the first non-emission area NEA1 is greater than the fifth thickness t2-1b of the fifth auxiliary black matrix 396a2 positioned correspondingly to the second non-emission area NEA2. The fifth thickness t2-1b of the fifth auxiliary black matrix 396a2 positioned correspondingly to the second non-emission area NEA2 is greater than the fourth thickness t2-2 of the fourth auxiliary black matrix 396b positioned correspondingly to the emission area EA.

The total optical density with regard to the black reflection visibility in the first non-emission area NEA1, the second non-emission area NEA2, and the emission area EA of the display device 300D illustrated in FIG. 15 may be calculated by the Equation 2-6, the Equation 3-6 and Equation 4-6 referring to FIG. 14, respectively.

The first thickness t1 of the first auxiliary black matrix 392, the third thickness t2-1a of the third auxiliary black matrix 396a1, the fifth thickness t2-1b of the fifth auxiliary black matrix 396a-2, and the fourth thickness t2-2 of the fourth auxiliary black matrix 396b may be the same with reference to FIG. 8.

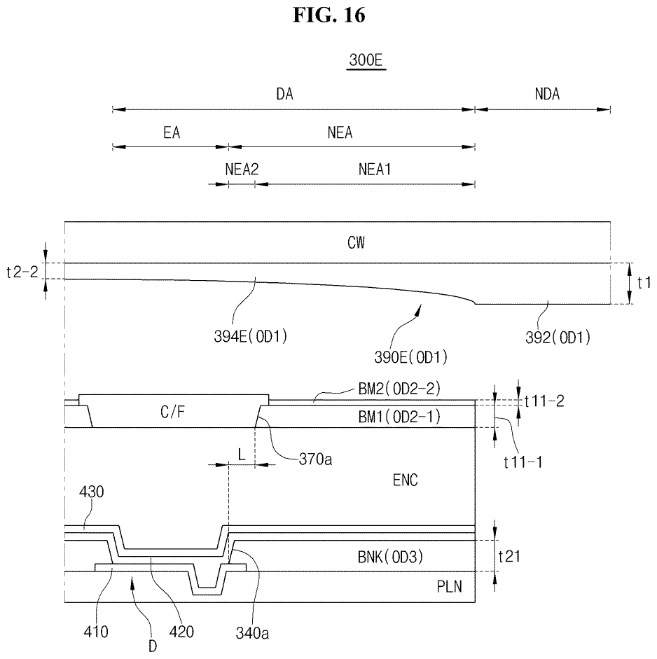

With reference to FIG. 16, the auxiliary black matrix 390E may be disposed under the cover window CW constituting the outmost of the display device 300E, in which the display device 300E may include the first auxiliary black matrix 392 positioned correspondingly to the non-display area NDA, and the second auxiliary black matrix 394E positioned correspondingly to the display area DA. The first thickness t1 of the first auxiliary black matrix 392 may be greater than the second thickness t2-2 of the second auxiliary black matrix 394E. The second auxiliary black matrix 394E may be configured such that the second thickness t2-2 gradually decreases from the first non-emission area NEA1 to the emission area EA via the second non-emission area NEA2.

### Third Embodiment

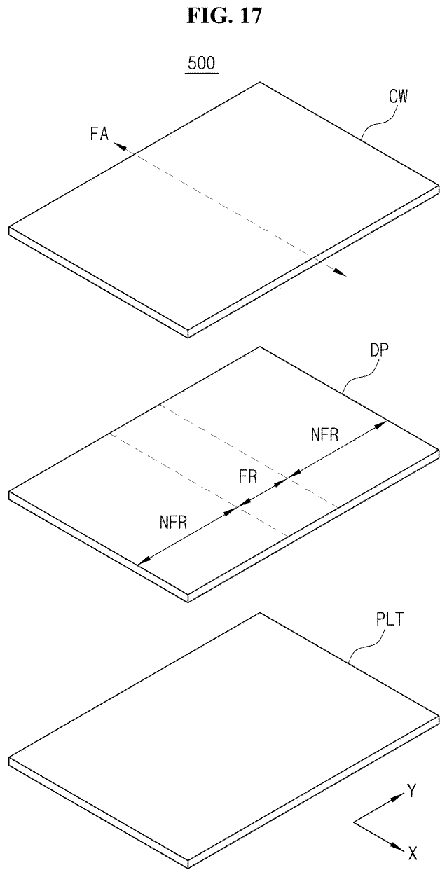

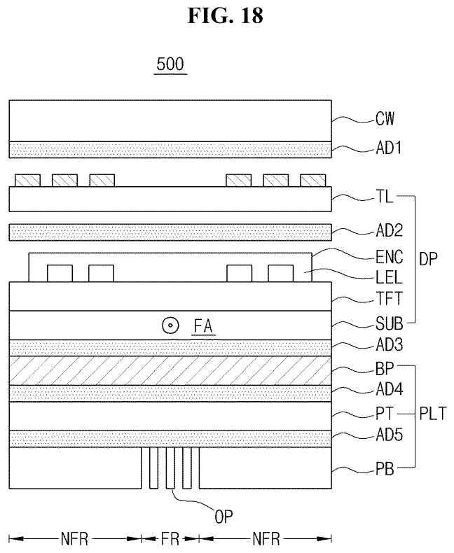

The display device in accordance with the inventive concepts may be a foldable display device. FIG. 17 illustrates a schematic exploded perspective view of a display device in accordance with a third embodiment of the inventive concepts. FIG. 18 illustrates a schematic cross-sectional view of the display device in accordance with the third embodiment of the inventive concepts.

Referring to FIGS. 17 and 18, a display device 500 may include a folding region FR and a non-folding region NFR, and may be folded along a first (Y) direction. The display device 500 may include the non-folding region NFR at both sides of the folding region FR along the first direction.

The display device 500 may be out-folded in which the display surface is exposed to the outside folded, but is not limited thereto. Alternatively or additionally, the display device 30 may be in-folded in which the display surface is hidden therein.

In one embodiment, a display panel DP may be folded inwardly or outwardly with respect to a folding axis FA. As used herein, the folding axis FA represents a center of the folding area having a predetermined curvature due to folding by an imaginary line. While the display panel DP is illustrated to be folded at a center portion in FIG. 17, the entire portion of the display panel DP may be freely deformed.

The display panel DP may include a substrate SUB including a flexible material so that the display area may be folded inwardly or outwardly, and an element layer for displaying an image. For example, the element layer may include a thin film transistor element layer TFT and a light emitting element layer LEL disposed in the display area on the substrate SUB.

An encapsulation layer ENC may be disposed on the light emitting element layer LEL, a touch layer (touch sensor) TL may be disposed on the encapsulation layer LED, and a cover window CW may be disposed on the touch layer TL. In addition, a color filter layer and/or a black matrix may be disposed on the touch layer TL, for example, between the touch layer TL and the cover window CW.

A plate PLT may be disposed on the lower surface of the substrate SUB for supporting the substrate SUB. For example, the plate PLT may include a back plate BP, a plate top PT, and a plate bottom PB disposed sequentially on the lower surface of the substrate SUB.

The thin film transistor element layer TFT may include a thin film transistor with a semiconductor layer, a gate electrode, a source electrode and a drain electrode, a gate insulating layer, and an interlayer insulating layer. The thin film transistor may have the structure illustrated in FIG. 3 or FIG. 10. The thin film transistor may be a driving thin film transistor and may include an oxide semiconductor.

The light emitting element layer LEL may include a light-emitting diode, a bank layer, a color filter pattern, a black matrix, and an auxiliary black matrix. The arrangements and/or shapes of the light-emitting diode, the bank layer, the color filter pattern, the black matrix and the auxiliary black matrix may be the same referring to FIGS. 3 to 16.

The substrate SUB on which the thin film transistor element layer TFT and the light emitting element layer LEL are disposed, may be encapsulated by the encapsulation layer ENC. The encapsulation layer ENC prevents or reduces external oxygen and/or moisture from infiltrating to the light emitting element layer LEL. The cover window CW constitutes an outer periphery of the display device 500.

The back plate BP may include an organic material with beneficial folding properties. For example, the back plate BP may include, but is not limited to, a polyimide (PI).

The plate top PT and the plate bottom PB may include a metal component, and the thickness of the plate bottom PB exposed to the outside may be larger than the thickness of the plate top PT. For example, the plate top PT may include SUS301 with relatively high hardness and the plate bottom PB may include SUS313 with higher corrosion resistance and acid resistance, but is not limited thereto.

The plate bottom PB may include a plurality of openings OP in the folding area FR so that the display device 500 may improve the folding property. In one embodiment, the plurality of openings OP may be configured to penetrate the surface and/or rear surface of the plate bottom PB.

A plurality of adhesive components AD1, AD2, AD3, AD4, and AD5 may be disposed among the plurality of components in the display device 500. For example, a first adhesive component AD1 may be disposed between the touch layer TL and the cover window CW, a second adhesive component AD2 may be disposed between the encapsulation layer ENC and the touch layer TL, a third adhesive component AD3 may be disposed between the substrate SUB and the back plate BP, a fourth adhesive component AD4 may be disposed between the back plate BP and the plate top PT, and a fifth adhesive component AD5 may be disposed between the plate top PT and the plate bottom PB. Each of the first to fifth adhesive components AD1, AD2, AD3, AD4, and AD5 may include an optically clear adhesive (OCA) and/or a pressure sensitive adhesive (PSA).

In accordance with the third embodiment, it is possible to implement the display device 500 having a uniform reflection visibility in the entire area, minimizing or reducing stains caused by the reflection of the external light, and having good luminous brightness. In particular, the foldable display with beneficial flexibility by omitting a polarizer may be fabricated. The display device implementing ESG may be manufactured with the advantages of low reflection and low power. [0264][Example]

The optical density and thickness of the bank layer, the black matrix, and the auxiliary black matrix illustrated in FIG. 11 were designed as shown in Table 1 below, and the total optical density OD for each area was calculated. The first optical density OD1 per 1 μm thickness of the auxiliary black matrix BM was set to 1.458, each of the second optical densities OD2-1 and OD2-2 per 1 μm thickness of the first black matrix BM1 and the second black matrix BM2 was set to 1.3, and the third optical density OD3 per 1 μm thickness of the bank layer was set to 0.8.

For comparison, the auxiliary black matrix was placed only in the non-display area, and a single black matrix was applied to calculate the total optical density for each area. The optical density for each configuration was calculated by multiplying the optical density per unit thickness by the thickness. The transmittance T was calculated using the following equation and converted into percentage.

$$T = 1 {0}^{- OD}$$

TABLE 1
Total Optical Density and Transmittance by Areas in Display Device

| | | unit OD | NDA | NEA1 | NEA2 | EA |
|---|---|---|---|---|---|---|
| Sample | Components | (μm) | (thickness) | (thickness) | (thickness) | (thickness) |
| Reference | Auxiliary | 1.458 | OD: 3.50 | — | — | — |
| (Comparative | BM | | (2.4 μm) | | | |
| Example) | BM | 1.3 | — | OD: 1.95 | — | — |
| | | | | (1.5 μm) | | |
| | Bank layer | 0.8 | — | OD: 1.2 | OD: 1.2 | — |
| | | | | (1.5 μm) | (1.5 μm) | |
| | Total OD | | 3.50 | 3.15 | 1.2 | 0 |
| | Transmittance (%) | | 0.03 | 0.07 | 6.31 | 100 |
| Example | Auxiliary | 1.458 | OD: 3.50 | OD: 0.15 | OD: 0.15 | OD: 0.15 |
| | BM | | (2.4 μm) | (0.1 μm) | (0.1 μm) | (0.1 μm) |
| | BM2 | 1.3 | — | OD: 0.78 | — | — |
| | | | | (0.6 μm) | | |
| | BM1 | 1.3 | — | OD: 1.3 | — | — |
| | | | | (1.0 μm) | | |
| | Bank layer | 0.8 | — | OD: 1.2 | OD: 0.12 | — |
| | | | | (1.5 μm) | (1.5 μm) | |

| | | | | |
|---|---|---|---|---|
| Total OD | 3.50 | 3.43 | 1.35 | 0.15 |
| Transmittance (%) | 0.03 | 0.04 | 4.51 | 71.5 |

| | | | | |
|---|---|---|---|---|
| Transmittance Difference (%) | — | 0.03 | 1.8 | 28.5 |

Referring to Table 1, in the Comparative Example, the total optical density and the transmittance in the first non-emission area NEA1 in which the bank layer and the black matrix are overlapped was 3.15 and 0.0700, respectively. In the example, the total optical density and the transmittance in the first non-emission area NEA was 3.43 and 0.040%, respectively. Compared to the Comparative Example, the transmittance in the first non-emission area NEA1 decreased by 0.0300 in the Example, making it uniform close to the transmittance in the non-display area NDA.

In the Comparative Example, the total optical density and the transmittance in the second non-emission area NEA2 was 1.2 and 6.31%, respectively. In the Example, the total optical density and the transmittance in the second non-emission area NEA2 was 1.35 and 4.5%, respectively. Compared to the Comparative Example, the transmittance in the second non-emission area NEA2 decreased by 1.8% in the Example which was closer to the transmittance in the non-display area NDA.

In the Comparative Example, the total optical density and the transmittance in the emission area EA was 0 and 100%, respectively. In the Example, the total optical density and the transmittance in the emission area EA was 0.15 and 71.5%, respectively. Compared to the Comparative Example, the transmittance in the emission area EA decreased by 28.5%, but was closer to the transmittance in other areas.

Considering the results in Table 1, it was confirmed that a display device with improved black reflection visibility in the entire area may be implemented by arranging the bank layer, the black matrix and the auxiliary black matrix and adjusting the optical density and the thickness of these structure by the inventive concepts.

In one or more embodiments, since there is no need to apply a separate polarizer to the display surface, the luminance of light emitted from the light-emitting diode is not reduced. A portion of the external light may be absorbed or reflected by the auxiliary black matrix disposed adjacently to the display surface, so that the external light may be incident toward the internal display panel or the pad member through the same or similar light path in the entire areas.

The display device according to embodiments of the inventive concepts controls the external light path by the areas and overcomes the difference in length of the external light paths by the areas. In the display device, the deviation of external light reflection by the area may be minimized. Accordingly, it is possible to implement the display device in which the difference in black reflection visibility in the display area and the non-display area is minimized.

When the external light incident on the display area and the non-display area is reflected from electrodes inside the display panel, the external light may be absorbed and blocked in the bank layer, the black matrix, and the auxiliary black matrix. Accordingly, the reflection of the external light in the display device may be minimized or reduced.

In the display device according to embodiments, the rainbow mura that may be caused by light reflection of a conductive material such as a conducive film and/or an electrode inside the display panel, or by a difference in reflective index of the films through the reflected light passes may be minimized or reduced.

The display device according to embodiments may obviate the need of a separate polarizing member to improve flexibility thereof, and therefore, it is possible to implement a foldable display device in which the display area is folded.

The reflection of the external light may be efficiently suppressed even if the content of the light-blocking material the bank layer and the black matrix disposed in the non-emission area is not increased. Accordingly, the reliability and processability of the black matrix may be secured.

The side of the bank layer disposed adjacently to the light-emitting diode further extends to the emission area compared to the side of the black matrix disposed adjacently to the color filter layer, so that, the display device may secure beneficial viewing angle. In addition, since the plurality of black matrices may be disposed adjacently to the color filter pattern may be disposed, the display device may further improve the viewing angle. A low-reflection display device may be implemented, and ESG may be implemented proving the advantage of low power consumption by disposing uneven patterns on the lower surface, if necessary, of the upper surface of the black matrix.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device, comprising:
a substrate having a non-display area and a display area, the display area including an emission area and a non-emission area;
a light-emitting diode disposed in the emission area;
a bank layer disposed adjacently to the light-emitting diode in the non-emission area;
an encapsulation layer disposed on the light-emitting diode and the bank layer;
a color filter pattern disposed on the encapsulation layer in the emission area;
a black matrix disposed on the encapsulation layer in the non-emission area; and
an auxiliary black matrix disposed on the substrate in the non-display area and the auxiliary black matrix is disposed on the color filter pattern and the black matrix in the display area,
wherein the auxiliary black matrix disposed in the non-display area has a first thickness that is thicker than a second thickness of the auxiliary black matrix disposed in the display area.

2. The display device of claim 1, wherein a first portion of the auxiliary black matrix positioned correspondingly to the emission area on the color filter pattern has a thickness substantially the same as a thickness of a second portion of the auxiliary black matrix positioned correspondingly to the non-emission area on the black matrix.

3. The display device of claim 1, wherein a first portion of the auxiliary black matrix positioned correspondingly to the non-emission area on the black matrix has a third thickness different form a fourth thickness of a second portion of the auxiliary black matrix positioned in the emission area on the color filter pattern.

4. The display device of claim 1, wherein the non-emission area comprises:
a first non-emission area where the bank layer and the black matrix are disposed to overlap; and
a second non-emission area where the bank layer is disposed to extend further toward the emission area than the black matrix.

5. The display device of claim 4, wherein a first portion of the auxiliary black matrix positioned correspondingly to the first non-emission area has a third thickness different from a fourth thickness of a second portion of the auxiliary black matrix positioned correspondingly to the second non-emission area.

6. The display device of claim 4, wherein a first portion of the auxiliary black matrix positioned correspondingly to the emission area on the color filter pattern has a third thickness different from a fourth thickness of a second portion of the auxiliary black matrix positioned correspondingly to the second non-emission area.

7. The display device of claim 4, wherein a first portion of the auxiliary black matrix positioned correspondingly to the second non-emission area has a third thickness greater than a fourth thickness of a second portion of the auxiliary black matrix positioned correspondingly to the emission area on the color filter pattern and greater than a fifth thickness of a third portion of the auxiliary black matrix positioned correspondingly to the first non-emission area.

8. The display device of claim 4, wherein a first portion of the auxiliary black matrix positioned correspondingly to the first non-emission area has a third thickness greater than a fifth thickness of a second portion of the auxiliary black matrix positioned correspondingly to the second non-emission area, and wherein the fifth thickness is greater than a fourth thickness of a third portion of the auxiliary black matrix positioned correspondingly to the emission area.

9. The display device of claim 1, wherein the second thickness gradually decreases from a first portion of the auxiliary black matrix disposed in the non-emission area to a second portion of the auxiliary black matrix disposed in the emission area.

10. The display device of claim 1, wherein the auxiliary black matrix has a first optical density per unit thickness greater than a second optical density per unit thickness of the black matrix.

11. The display device of claim 1, wherein the black matrix has a second optical density per unit thickness greater than a third optical density per unit thickness of the bank layer.

12. The display device of claim 1, wherein the black matrix comprises:
a first black matrix disposed on the encapsulation layer in the non-emission area; and
a second black matrix disposed on the first black matrix in the non-emission area.

13. The display device of claim 12, wherein the first black matrix has a thickness equal to or greater than a thickness of the second black matrix.

14. The display device of claim 12, wherein the auxiliary black matrix has a first optical density per unit thickness greater than a second optical density per unit thickness of the first black matrix and the second black matrix.

15. The display device of claim 12, wherein the first black matrix and the second black matrix have a second optical density per unit thickness greater than a third optical density per unit thickness of the bank layer.

16. The display device of claim 1, wherein a peripheral region of the bank layer which is in contact with the light-emitting diode is further extended toward the emission area than a peripheral area of the black matrix which is in contact with the color filter pattern.

17. The display device of claim 1, wherein the bank layer comprises a colorant selected from at least one of a black dye and a black pigment.

18. The display device of claim 1, wherein a side of the bank layer that is in contact with the light-emitting diode has a cross-section inclined downwardly toward the emission area.

19. The display device of claim 1, wherein the display device further comprises:
a driving thin film transistor disposed on the substrate and the driving thin film transistor is connected to the light-emitting diode;
a touch sensor disposed between the encapsulation layer, and the black matrix and the color filter pattern; and
a cover window disposed on the auxiliary black matrix.

20. The display device of claim 19, wherein the driving thin film transistor comprises an oxide semiconductor.
